(19) United States
(12) Patent Application Publication
(10) Pub. No.: US 2025/0293156 A1
(43) Pub. Date: Sep. 18, 2025

(54) MERGED CONTROL LINE FORMATION FOR MEMORY WITH VERTICAL TRANSISTORS

(71) Applicant: Intel Corporation, Santa Clara, CA (US)

(72) Inventor: Abhishek A. Sharma, Portland, OR (US)

(73) Assignee: Intel Corporation, Santa Clara, CA (US)

(21) Appl. No.: 18/604,834

(22) Filed: Mar. 14, 2024

(51) Int. Cl. H01L 23/528; G11C 5/06; G11C 16/04; H10B 43/10; H10B 43/27

(52) U.S. Cl. CPC H01L 23/5283; G11C 5/063; G11C 16/0483; H10B 43/10; H10B 43/27

(57) ABSTRACT

Integrated circuit (IC) devices including an array of memory cells and merged control lines are described herein. In one example, memory cells coupled with a common control line are arranged two or more lines staggered with respect to one another. In one example, the control line includes a continuous conductive material between closely-spaced adjacent memory cells coupled with the control line. In one example, a method of fabricating an IC device with an array of memory cells and merged control lines includes using the geometric layout and width of a spacer material to achieve self-aligned merged control lines.

### BACKGROUND

Embedded memory is important to the performance of modern system-on-a-chip (SoC) technology. Low power and high-density embedded memory is used in many different computer products and further improvements are always desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1B are electric circuit diagrams of a hysteretic memory cell that may be implemented using a vertical transistor and a merged control line, according to some embodiments of the present disclosure.

FIGS. 2A-2B are electric circuit diagrams of an array of a plurality of hysteretic memory cells of, respectively, FIG. 1A and FIG. 1B, according to some embodiments of the present disclosure.

FIGS. 3A-3C provide various views of an example integrated circuit (IC) device that may be used to implement a hysteretic memory cell of FIG. 1A with a vertical transistor and a merged control line, according to some embodiments of the present disclosure.

FIGS. 4A-4C provide various views of another example IC device that may be used to implement a hysteretic memory cell of FIG. 1A with a vertical transistor and a merged control line, according to other embodiments of the present disclosure.

FIGS. 5A-5B provide various views of an example IC device implementing a memory cell with a vertical transistor and a capacitor, according to some embodiments of the present disclosure.

FIGS. 6A-6B provide various views of another example IC device implementing a memory cell with a vertical transistor and a capacitor, according to other embodiments of the present disclosure.

FIGS. 7A-7C and 8-13 provide various views of example IC devices implementing an array of a plurality of memory cells with vertical transistors and merged control lines, according to other embodiments of the present disclosure.

FIG. 14 is a flow diagram of an example method for fabricating an IC device with an array of memory cells and merged control lines, in accordance with some embodiments.

FIGS. 15A-5D, 16A-16D, 17A-17D, 18A-18D, and 19A-19D are different views at various stages in the fabrication of an example IC structure according to the method of FIG. 14, in accordance with some embodiments.

FIG. 20 is a flow diagram of another example method for fabricating an IC device with an array of memory cells and merged control lines, in accordance with some embodiments.

FIGS. 21-24 are cross-sectional side views at various stages in the fabrication of an example IC structure according to the method of FIG. 20, in accordance with some embodiments.

FIG. 25 provides top views of a wafer and dies that may include one or more IC devices implementing memory with vertical transistors and merged control lines in accordance with any of the embodiments disclosed herein.

FIG. 26 is a cross-sectional side view of an IC package that may include one or more IC devices implementing memory with vertical transistors and merged control lines in accordance with any of the embodiments disclosed herein.

FIG. 27 is a cross-sectional side view of an IC device assembly that may include one or more IC devices implementing memory with vertical transistors and merged control lines in accordance with any of the embodiments disclosed herein.

FIG. 28 is a block diagram of an example computing device that may include one or more IC devices implementing memory with vertical transistors and merged control lines in accordance with any of the embodiments disclosed herein.

### DETAILED DESCRIPTION

Described herein are integrated circuit (IC) structures implementing memory with vertical transistors and merged control lines and corresponding methods and devices. The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC devices implementing memory with vertical transistors and merged control lines as described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to IC components, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Memory with vertical transistors and merged control lines as described herein may be particularly advantageous for, although not limited to, implementing hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a volage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

In general, READ and WRITE access to a hysteretic memory cell (i.e., performance of READ and WRITE operations) is realized using a combination of a wordline, a bitline, and a plateline, each of which is an electrically conductive line to which a certain voltage is applied to sense (i.e., READ) or program (i.e., WRITE) a memory state of a hysteretic memory cells. Together, such electrically conductive lines are referred to herein as “control lines” because they are used to control a memory state of a memory cell. Control lines may also be referred to as conductive lines, conductive access lines, or access lines.

Hysteretic memories have the potential for adequate non-volatility, short programming time, low power consumption, high endurance, and high speed writing. In addition, hysteretic memories may be manufactured using processes compatible with the standard complementary metal-oxide-semiconductor (CMOS) technology. Therefore, over the last few years, these types of memories have emerged as promising candidates for many growing applications. Some memory technologies have limitations in terms of, e.g., the memory density, and fabrication approaches. For example, the arrangement of memory cells in conventional memory arrays can result in inefficient usage of space and sub-optimal density.

Embodiments of the present disclosure may improve on at least some of the challenges and issues of existing memory arrays by increasing memory density and/or improving the fabrication techniques (e.g., by lowering cost and/or reducing defects). In particular, embodiments of the present disclosure provide various arrangements for IC devices implementing memory with vertical transistors and merged control lines. A vertical transistor is a type of a field-effect transistor (FET) where the source and the drain terminals of the transistor are vertically stacked with respect to a support structure (e.g., a substrate, a die, a wafer, or a chip) on which the transistor is implemented.

In one aspect of the present disclosure, an example IC device with a memory array and merged control lines includes a plurality of memory cells arranged in two or more lines staggered with respect to one another over the substrate, including a first line and a second line adjacent to the first line, and a control line (e.g., a “merged control line”) coupled with the plurality of memory cells, where the control line is substantially parallel to the two or more lines of memory cells. The control line includes a continuous conductive material between an adjacent pair of memory cells. For example, the control line includes a continuous conductive material between and in contact with a first memory cell of the first line and a second memory cell of the second line, where the second memory cell is a nearest neighboring memory cell of the second line to the first memory cell. In one example, a line between a first centroid of the first memory cell and a second centroid of the second memory cell is at an angle in a range of about 30-60 degrees, and in some examples, is less than 60 degrees. In one such example, a relatively shallow angle (compared to previous staggering techniques) may enable arranging the memory cells in more than two lines staggered with respect to one another, increasing the density of the memory array. In one example, an IC device with a memory array and merged control lines may be fabricated with a technique that uses the geometric layout of memory cell openings and the width of a spacer material to achieve self-aligned merged control lines without additional lithographic processes.

In some embodiments, the vertical transistor may be a hysteretic transistor. In other embodiments, the vertical transistor may be further coupled to a hysteretic capacitor. As used herein, a transistor is referred to as a “hysteretic transistor” if, instead of or in addition to a conventional gate dielectric material, the transistor includes a hysteretic material or a hysteretic arrangement as a gate insulator. On the other hand, a capacitor is referred to as a “hysteretic capacitor” if, instead of or in addition to a conventional dielectric material, the capacitor includes a hysteretic material or a hysteretic arrangement as a capacitor insulator that separates first and second capacitor electrodes. An individual one of the multiple hysteretic transistors or hysteretic capacitors may store a memory state, thus realizing a memory cell of a memory array.

In the following, descriptions are provided with respect to bitlines being the control lines that wrap around portions of vertical transistors, and which include continuous (e.g., merged) portions between adjacent pairs of memory cells, and with the platelines being the control lines coupled to the bottom portions of the vertical transistors. However, in general, these descriptions are equally applicable to embodiments where the designations of bitlines and platelines are reversed (i.e., where platelines are the merged control lines). In other examples, wordlines may be implemented as merged control lines. Some descriptions refer to features or components as being adjacent to one another or neighboring one another. In one such example, a feature or component may be adjacent to or neighboring multiple other features/components, and descriptions referring to an adjacent feature or component do not imply the absence of other adjacent features/components. Additionally, some descriptions refer to memory cells being arranged (e.g., organized, implemented, laid out, etc.) in one or more lines. Such descriptions intend to encompass real IC devices in which memory cells are organized into line(s) that may not be perfectly straight (e.g., due to process limitations, defects, etc.). In the context describing various layers in the present disclosure, the term “above” may refer to a layer being further away from a support structure of an IC device, while the term “below” refers to a layer being closer to the support structure. Although descriptions of the present disclosure may refer to logic devices or memory cells provided in a given layer, each layer of the IC devices described herein may also include other types of devices besides logic or memory devices described herein.

As used herein, a “memory state” (or, alternatively, a “logic state,” a “state,” or a “bit” value) of a memory cell refers to one of a finite number of states that the cell can have, e.g., logic states “1” and “0.” When any of the memory cells as described herein use a hysteretic material such as a FE or an AFE material, in some embodiments, a logic state of the memory cell may be represented simply by presence or absence of polarization of a FE or an AFE material in a certain direction (for example, for a two-state memory where a memory cell can store one of only two logic states-one logic state representing the presence of polarization in a certain direction and the other logic state representing the absence of polarization in a certain direction). In other embodiments of memory cells that include hysteretic materials such as FE or AFE materials, a logic state of a memory cell may be represented by the amount of polarization of a FE or an AFE material in a certain direction (for a multi-state memory where a memory cell can store one of three or more logic states, where different logic states represent the presence of different amounts of polarization in a certain direction). When any of the memory cells as described herein use a charge-trapping hysteretic arrangement, in some embodiments, a logic state of a memory cell may be represented simply by presence or absence of charge trapped in a charge-trapping hysteretic arrangement (for example, for a two-state memory where a memory cell can store one of only two logic states-one logic state representing the presence of charge and the other logic state representing the absence of charge). In other embodiments of memory cells that include charge-trapping hysteretic arrangements, a logic state of a memory cell may be represented by the amount charge trapped in a charge-trapping hysteretic arrangement (for example, for a multi-state memory where a memory cell can store one of three or more logic states, where different logic states represent the presence of different amounts of trapped charges). As used herein, “READ” and “WRITE” memory access or operations refer to, respectively, determining/sensing a logic state of a memory cell and programming/setting a logic state of a memory cell.

In the following detailed description, various aspects of the illustrative implementations may be described using terms commonly employed by those skilled in the art to convey the substance of their work to others skilled in the art. For example, in context of S/D regions, the term “region” may be used interchangeably with the terms “contact” and “terminal” of a transistor. In another example, as used herein, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, analogous elements designated in the present drawings with different reference numerals after a dash, e.g., bitlines 140-1, 140-2, and so on may be referred to together without the reference numerals after the dash, e.g., as “bitlines 140.” In order to not clutter the drawings, if multiple instances of certain elements are illustrated, only some of the elements may be labeled with a reference sign.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices implementing memory with vertical transistors and merged control lines as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices implementing memory with vertical transistors and merged control lines as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

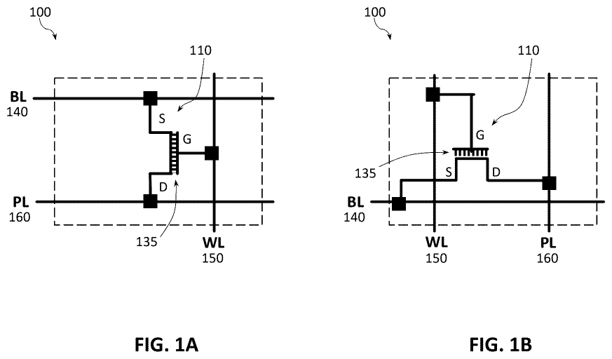

FIGS. 1A-1B are electric circuit diagrams of a hysteretic memory cell 100 that may be implemented using a vertical transistor 110 and a bitline 140, according to some embodiments of the present disclosure. As shown in FIG. 1, the transistor 110 has a gate terminal, a source terminal, and a drain terminal, labeled in this and some of the other drawings as terminals G, S, and D, respectively. A bitline 140 (labeled in this and some of the other drawings as “BL”), a wordline 150 (labeled in this and some of the other drawings as “WL”), and a plateline 160 (labeled in this and some of the other drawings as “BL”) are coupled to different terminals of the transistor 110.

As is commonly known, the designation of source and drain terminals in a transistor may be interchangeable in certain implementations. Therefore, while the example of FIGS. 1A-1B illustrates the bitline 140 to be coupled to a source terminal and the plateline 160 be coupled to a drain terminal, in other embodiments, this arrangement may be reversed. Together, source and drain terminals of a transistor may be referred to as a “transistor terminal pair,” where the individual ones of these two terminals may be referred to as a “first source or drain (S/D) terminal” and a “second S/D terminal” (e.g., if the first S/D terminal is a source terminal, then the second S/D terminal is a drain terminal, and vice versa). The same applies to S/D regions of the transistor 110 (i.e., the designation of source and drain regions of a transistor may be interchangeable), where, in general, S/D regions of a transistor (also sometimes interchangeably referred to as “diffusion regions”) may be regions of doped semiconductors, e.g., regions of a doped channel material, so as to supply charge carriers for the transistor channel. Often, the S/D regions are highly doped, e.g., with dopant concentrations of about 1·10²¹ dopants per cubic centimeter (cm⁻³), in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the S/D regions of the transistor 110 may be the regions having dopant concentration higher than in other regions, e.g., higher than a dopant concentration in the transistor channel (i.e., in a channel material extending between the source region and the drain region), and, therefore, may be referred to as “highly doped” (HD) regions. The channel material of a transistor may include one or more semiconductor materials with doping concentrations significantly smaller than those of the S/D regions. For example, in some embodiments, the channel material may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material of the transistor 110 are still significantly lower than the dopant level in the S/D regions, for example below 10¹⁵ cm⁻³, or below 10¹³ cm⁻³. Depending on the context, the term “S/D terminal” may refer to a S/D region or a S/D contact or electrode of a transistor.

In various embodiments, the transistor 110 may be any FET, e.g., the transistor 110 may be either an N-type metal-oxide-semiconductor (NMOS) transistor or a P-type metal-oxide-semiconductor (PMOS) transistor. In some embodiments particularly suitable for implementing vertical transistors as described herein, the transistor 110 may be a thin-film transistor (TFT). A TFT is a special kind of a FET made by depositing a thin film of an active semiconductor material, as well as a dielectric layer and conductive (e.g., metallic) contacts, over a supporting layer that may be a non-conductor layer and a non-semiconductor layer. At least a portion of the active semiconductor material forms a channel region/material of the TFT. This is different from conventional, non-TFT, front-end-of line (FEOL) transistors where the semiconductor channel material of a transistor is typically a part of a semiconductor substrate, e.g., a part of a silicon wafer, or is epitaxially grown on a semiconductor substrate. Using TFTs as transistors of memory cells provides several advantages and enables unique architectures that were not possible with conventional, FEOL logic transistors. For example, advantages include substantially lower leakage in TFTs than in logic transistors and lower temperature processing used to fabricate TFTs. In context of the present disclosure, the transistor 110 being a TFT advantageously allows depositing a thin-film channel material of the transistor 110 in a non-planar arrangement to realize vertical transistor architecture, as will be described in greater detail below.

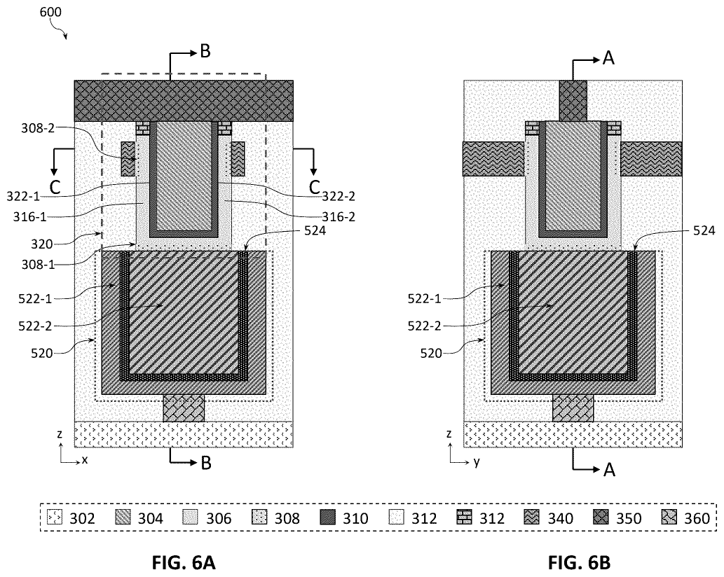

The transistor 110 is different from conventional logic transistors in that, instead of or in addition to a gate dielectric material that may be included in the gate, the transistor 110 further includes a hysteretic material or a hysteretic arrangement, which, together, may be referred to as a “hysteretic element 135” (schematically illustrated in FIG. 1 as short parallel vertical lines integrated with the notation of the gate of the transistor 110). In this manner, the hysteretic element 135 of the memory cell 100 is integrated into the gate of the transistor 110 and the transistor 110 may be described as a “hysteretic transistor.” The hysteretic element 135 integrated in the gate of the transistor 110 (or used as a capacitor insulator of a storage capacitor of a memory cell, described below with reference to FIG. 6A or FIG. 6B, in which case the storage capacitor may be described as a “hysteretic capacitor”) may have a thickness that may, in some embodiments, be between about 0.5 nanometers and 10 nanometers, including all values and ranges therein (e.g., between about 1 and 8 nanometers, or between about 0.5 and 5 nanometers).

In some embodiments, the hysteretic element 135 may be provided as a layer of an FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element 135 and are within the scope of the present disclosure.

In other embodiments, the hysteretic element 135 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell.

In some embodiments of the hysteretic element 135 being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element 135 being provided as a stack of alternating layers of materials that can trap charges, a thickness of each layer of the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element 135 provided as a stack of alternating layers of materials that can trap charges (i.e., a hysteretic arrangement) may be between about 1 and 10 nanometers, e.g., between about 2 and 8 nanometers, e.g., about 6 nanometers.

Together, the bitline 140, the wordline 150, and the plateline 160 may be used to read and program the bit state of the memory cell 100 by, respectively, sensing and setting the polarization of the memory material (e.g., of the hysteretic element 135). Each of the bitline 140, the wordline 150, and the plateline 160, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

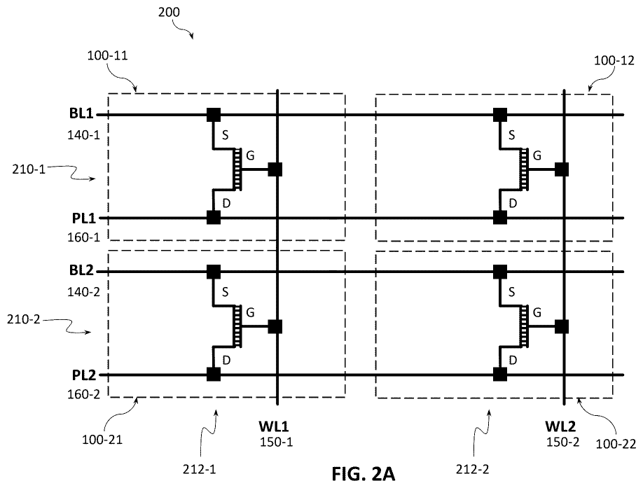

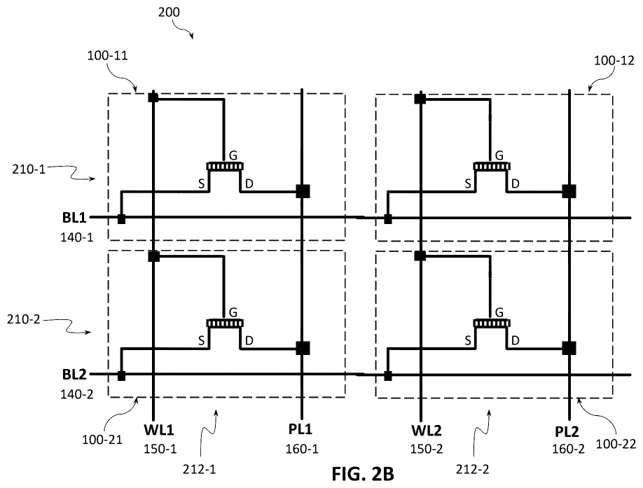

The memory cell 100 shown in FIG. 1A and the memory cell 100 shown in FIG. 1B have identical connections between various elements shown, but differ in the relative orientations of bitlines 140, wordlines 150, and platelines 160. In particular, FIG. 1A illustrates an embodiment of the memory cell 100 where the plateline 160 is parallel to the bitline 140, while FIG. 1B illustrates an embodiment of the memory cell 100 where the plateline 160 is parallel to the bitline 140. Both FIGS. 1A and 1B illustrate embodiments of the memory cell 100 where the wordline 150 is perpendicular to the bitline 140. In some implementations, the relative orientations of bitlines 140, wordlines 150, and platelines 160 as shown in the electric circuit diagrams of the present drawings (e.g., FIGS. 1 and 2) may be representative of actual physical orientations of these control lines in the actual physical layout of the IC devices described herein. For example, in some implementations, the wordlines 150 may indeed be routed as metal lines substantially parallel to one another and substantially perpendicular to the bitlines 140. In another example, in some implementations, the platelines 160 may indeed be routed as metal lines substantially parallel to one another and to the bitlines 140. However, in other implementations, any of the bitlines 140, wordlines 150, and platelines 160 may be oriented in the actual physical layout of any of the IC devices described herein in any manner that allows realizing the electrical connections as described with reference to FIGS. 1A-1B and FIG. 2A-2B.

The memory cell 100 as shown in FIGS. 1A-1B is a “unit cell,” where a plurality of such unit cells may be arranged in an array to implement a memory device. Each of the memory cells 100 as shown in FIGS. 1A-1B can be any one of the memory cells having the transistor 110 implemented as a vertical transistor and having a merged bitline 140 as described herein. Note that although some examples refer to a merged bitline, the techniques described herein may be used for any control line (e.g., bitline, wordline, or plateline).

FIG. 2A provides a schematic illustration of a plurality of memory cells 100 of FIG. 1A, namely four cells, arranged in an array 200, according to some embodiments of the present disclosure. Similarly, FIG. 2B provides a schematic illustration of a plurality of memory cells 100 of FIG. 1B, namely four cells, arranged in an array 200, according to some embodiments of the present disclosure. Individual memory cells 100 of FIG. 1A are illustrated in FIG. 2A to be within one of the dashed boxes labeled 100-11, 100-12, 100-21, and 100-22, and the same applies to the individual memory cells 100 of FIG. 1B that are illustrated in FIG. 2B. While only four memory cells 100 are shown in each of FIG. 2A and FIG. 2B, in other embodiments, the array 200 of FIGS. 2A-2B may, and typically would, include many more memory cells. Furthermore, in other embodiments, the memory cells 100 may be arranged in arrays in a manner other than what is shown in FIGS. 2A-2B, e.g., in any suitable manner of arranging memory cells into arrays as known in the art, all of which being within the scope of the present disclosure.

In some embodiments of the memory array 200, each of the bitline 140, wordline 150, and plateline 160 coupled to one memory cell can be shared among multiple, possibly different subsets of, the memory cells 100 of a memory array. Each of FIGS. 2A-2B illustrates one such embodiment where, as shown, the bitline 140 can be shared among multiple memory cells 100 in a column 210, and each of the wordline 150 can be shared among multiple memory cells 100 in a row 212. As is conventionally used in context of memory, the terms “row” and “column” do not reflect the, respectively, horizontal and vertical orientation on a page of a drawing illustrating a memory array but, instead, reflect how individual memory cells are addressed. Namely, memory cells 100 sharing a single bitline are said to be in the same column, while memory cells sharing a single wordline are said to be on the same row. Thus, in FIGS. 2A-2B, the horizontal lines of the memory cells 100 are referred to as columns 210-1 and 210-2, while the vertical lines of the memory cells 100 are referred to as rows 212-1 and 112-2. More specifically, as shown in FIGS. 2A-2B, the first column 210-1 includes the memory cells 100-11 and 100-12, each of which is coupled to the first bitline (BL1) 140-1; the second column 210-1 includes the memory cells 100-21 and 100-22, each of which is coupled to the second bitline (BL2) 140-2, the first row 212-1 includes the memory cells 100-11 and 100-21, each of which is coupled to the first wordline (WL1) 150-1, and the second row 212-2 includes the memory cells 100-12 and 100-22, each of which is coupled to the second wordline (WL2) 150-2.

FIGS. 2A and 2B differ in how the platelines 160 are shared among different memory cells 100 of the memory arrays 200. In particular, FIG. 2A illustrates an embodiment where a single plateline 160 may be shared among multiple memory cells of a given column 210. For example, FIG. 2A illustrates that the PL1 160-1 is shared among memory cells 100-11 and 100-12 of the column 210-1, while the PL2 160-2 is shared among memory cells 100-21 and 100-22 of the column 210-2. As described above, the BL1 is shared among memory cells 100-11 and 100-12 of the column 210-1, while the BL2 is shared among memory cells 100-21 and 100-22 of the column 210-2. Thus, in FIG. 2A, the platelines 160 are shared among the same memory cells among which the bitlines 140 are shared. Such an arrangement where the platelines 160 are shared among the same memory cells among which the bitlines 140 are shared may be described as an arrangement where the platelines 160 are “parallel” to the bitlines 140. Each memory cell 100 of the memory array 200 where the platelines 160 are parallel to the bitlines 140, e.g., as shown in FIG. 2A, may then be addressed (e.g., to perform READ and WRITE operations) by using the bitline 140 and the plateline 160 corresponding to the column 210 to which the memory cell 100 belongs and by using the wordline 150 corresponding to the row 212 to which the memory cell 100 belongs. For example, the memory array 200 of FIG. 2A, the memory cell 100-11 is controlled by WL1, BL1, and PL1, the memory cell 100-12 is controlled by WL2, BL1, and PL1, the memory cell 100-21 is controlled by WL1, BL2, and PL2, and the memory cell 100-22 is controlled by WL2, BL2, and PL2.

On the other hand, FIG. 2B illustrates an embodiment where a single plateline 160 may be shared among multiple memory cells of a given row 212. For example, FIG. 2B illustrates that the PL1 is shared among memory cells 100-11 and 100-21 of the row 212-1, while the PL2 is shared among memory cells 100-12 and 100-22 of the row 212-2. As described above, the WL1 is shared among memory cells 100-11 and 100-21 of the row 212-1, while the WL2 is shared among memory cells 100-12 and 100-22 of the row 212-2. Thus, in FIG. 2B, the platelines 160 are shared among the same memory cells among which the wordlines 150 are shared. Such an arrangement where the platelines 160 are shared among the same memory cells among which the wordlines 150 are shared may be described as an arrangement where the platelines 160 are “parallel” to the wordlines 150. Each memory cell 100 of the memory array 200 where the platelines 160 are parallel to the wordlines 150, e.g., as shown in FIG. 2B, may then be addressed (e.g., to perform READ and WRITE operations) by using the wordline 150 and the plateline 160 corresponding to the row 212 to which the memory cell 100 belongs and by using the bitline 140 corresponding to the column 210 to which the memory cell 100 belongs. For example, the memory array 200 of FIG. 2B, the memory cell 100-11 is controlled by WL1, PL1, and BL1, the memory cell 100-12 is controlled by WL2, PL2, and BL1, the memory cell 100-21 is controlled by WL1, PL1, and BL2, and the memory cell 100-22 is controlled by WL2, PL2, and BL2.

It should be noted that, just as the horizontal and vertical orientations on a page of an electrical circuit diagram illustrating a memory array does imply functional division of memory cells into rows and columns as used in common language, the orientation of various elements on a page of an electrical circuit diagram illustrating a memory array does not imply that the same orientation is used for the actual physical layout of a memory array. For example, in an IC device implementing the memory array 200 as shown in FIG. 2A, corresponding bitlines 140 and platelines 160 (i.e., a pair of a bitline 140 and a plateline 160 coupled to a given column 210) do not have to physically extend in a direction parallel to one another (although they may), or the wordlines 150 do not have to physically extend in a direction perpendicular to the bitlines 140 (although they may). In another example, in an IC device implementing the memory array 200 as shown in FIG. 2B, corresponding wordlines 150 and platelines 160 (i.e., a pair of a wordline 150 and a plateline 160 coupled to a given row 212) do not have to physically extend in a direction parallel to one another (although they may), or the wordlines 150 do not have to physically extend in a direction perpendicular to the bitlines 140 (although they may).

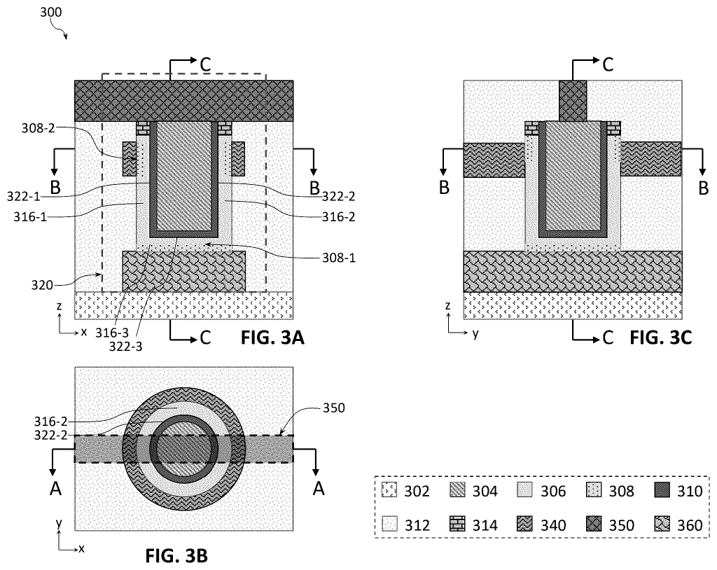

While FIGS. 1A-1B and 2A-2B provide schematic illustrations where the memory cells 100 are shown using their electrical circuit representations, FIGS. 3A-13 provide various views of example physical layouts of IC devices that may implement such memory cells according to various embodiments of the present disclosure. A number of elements labeled in FIGS. 3A-13 with reference numerals are indicated in FIGS. 3A-13 with different patterns in order to not clutter the drawings with too many reference numerals, with a legend showing the correspondence between the reference numerals and patterns being provided at the bottom or on the side of FIGS. 3A-13. For example, the legend illustrates that FIGS. 3A-3C use different patterns to show a support structure 302, a gate electrode material 304, a channel material 306, S/D regions 308, a gate insulator material 310, an insulator material 312, etc. Although some of the illustrations show embodiments where the platelines 160 are parallel to the bitlines 140, the same descriptions apply to embodiments where the platelines 160 are parallel to the wordlines 150, with necessary modifications to the illustrations being apparent in view of the descriptions provided herein. Therefore, unless specified otherwise, descriptions provided are applicable to the physical layouts of the IC devices where the platelines are parallel to the bitlines as well as to the embodiments where the platelines are parallel to the wordlines, all such embodiments of different physical layouts being within the scope of the present disclosure.

FIGS. 3A-3C provide various views of an example IC device 300 that may be used to implement a hysteretic memory cell 100 of FIG. 1A with a vertical transistor 320 and merged control lines, according to some embodiments of the present disclosure. In particular, FIG. 3B illustrates a cross-section of the IC device 300 taken along the section/plane B-B of FIGS. 3A and 3C, and FIG. 3C illustrates a cross-section of the IC device 300 taken along the section/plane C-C of FIG. 3A, while FIG. 3A illustrates a cross-section of the IC device 300 taken along the section/plane A-A of FIGS. 3B and 3C. With reference to an example coordinate system x-y-z that may be used to provide different views of an IC device, FIGS. 3A and 3C provide cross-sectional side views across planes x-z and y-z, respectively, while FIG. 3B provides a top-down view across a plane x-y, with a number of components not shown in the top-down view of FIG. 3B to more readily illustrate how the gate of the transistor 320 of the IC device 300 may be arranged.

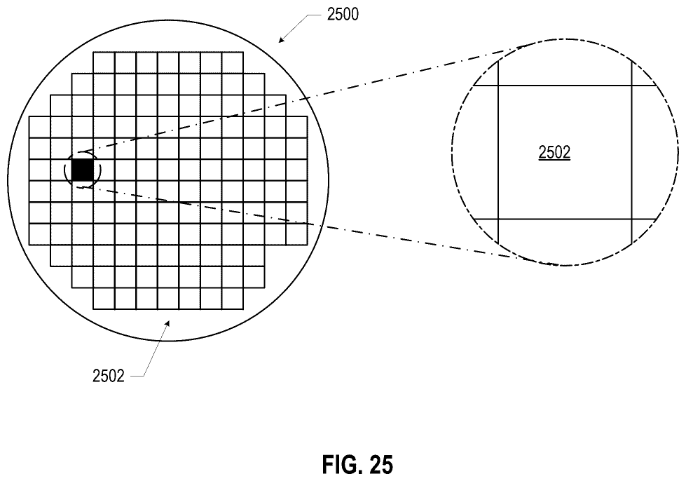

As shown in FIGS. 3A-3C, the IC device 300 includes a support structure 302, over which the transistor 320 may be provided. In general, implementations of the present disclosure may be formed or carried out on a substrate, such as a semiconductor substrate composed of semiconductor material systems including, for example, N-type or P-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V materials (i.e., materials from groups Ill and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which a semiconductor device may be built falls within the spirit and scope of the present disclosure. In various embodiments, the support structure 302 may include any such substrate that provides a suitable surface for providing the IC device with the memory cell 100. In some embodiments, the support structure 302 may be the wafer 2500 of FIG. 25, discussed below, and may be, or be included in, a die, e.g., the singulated die 2502 of FIG. 25, discussed below. In some embodiments, the support structure 302 may be a printed circuit board (PCB) substrate.

A portion of the IC device 300 within a rectangular dashed contour shown in FIG. 3A indicates an approximate outline of the transistor 320. As shown in FIGS. 3A-3C, the transistor 320 may include a gate electrode material 304, a channel material 306, and a pair of S/D regions 308 provided in the channel material 306. As also shown in FIGS. 3A-3C, a gate insulator material 310 may be integrated with the gate of the transistor 320 by being provided between the gate electrode material 304 and the channel material 306. FIGS. 3A-3C further illustrate an insulator material 312 that may surround various portions of the transistor 320 to provide electrical isolation between portions of the IC device 300. FIGS. 3A-3C also illustrate a bitline 340 (which may be an example of the bitline 140, described above), a wordline 350 (which may be an example of the wordline 150, described above), and a plateline 360 (which may be an example of the plateline 160, described above). As shown in FIGS. 3A-3C, the wordline 350 is electrically coupled to (e.g., in conductive contact with) the gate electrode material 304 of the transistor 320 (e.g., in some embodiments, the wordline 350 may serve as a contact to the gate of the transistor 320), but is electrically separated from the channel material 306 by means of a spacer material 314. As also shown in FIGS. 3A-3C, the plateline 360 is electrically coupled to (e.g., in conductive contact with) the first S/D region 308-1 of the pair of the S/D regions 308 of the transistor 320 (e.g., in some embodiments, the plateline 360 may serve as a contact to the first S/D region 308-1). FIGS. 3A-3C further illustrate that the bitline 340 is electrically coupled to (e.g., in conductive contact with) the second S/D region 308-2 of the pair of the S/D regions 308 of the transistor 320 (e.g., in some embodiments, the bitline 340 may serve as a contact to the second S/D region 308-2). The transistor 320 may be an example of the transistor 110, described above.

The gate electrode material 304 may include at least one P-type work function metal or N-type work function metal, depending on whether the transistor 320 is a PMOS transistor or an NMOS transistor (P-type work function metal used as a gate electrode material when the transistor 320 is a PMOS transistor and N-type work function metal used as a gate electrode material when the transistor 320 is an NMOS transistor). For a PMOS transistor, metals that may be used for the gate electrode material 304 may include, but are not limited to, ruthenium, palladium, platinum, cobalt, nickel, and conductive metal oxides (e.g., ruthenium oxide). For an NMOS transistor, metals that may be used for a gate electrode material 304 may include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, a gate electrode material 304 may include a stack of two or more metal layers, where one or more metal layers are work function metal layers and at least one metal layer is a fill metal layer. Further layers may be included next to a gate electrode material 304 for other purposes, such as to act as a diffusion barrier layer or/and an adhesion layer.

The channel material 306 may be composed of semiconductor material systems including, for example, N-type or P-type materials systems. In particular, the channel material 306 may be formed of a thin-film material. Some such materials may be deposited at relatively low temperatures, which allows depositing them within the thermal budgets imposed on back-end fabrication to avoid damaging the frontend components (not specifically shown in FIGS. 3A-3C) of the IC device 300. In some embodiments, the channel material 306 may have a thickness between about 1 and 75 nanometers, e.g., between about 1 nanometers and 10 nanometers or between about 5 nanometers and 30 nanometers, including all values and ranges therein. In some embodiments, the channel material 306 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 306 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous, polymorphous, or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

Whether the channel material 306 is a thin-film channel material, as opposed to an epitaxially grown semiconductor material that may be included in the IC device (e.g., by layer transfer or with other techniques), may be identified by inspecting grain size of the channel material 306. An average grain size of the channel material 306 being between about 0.5 and 1 millimeters (in which case the material may be considered to be polycrystalline) or smaller than about 0.5 millimeter (in which case the material may be considered to be polymorphous or amorphous) may be indicative of the channel material 306 being a thin-film material deposited onto portions of the IC device 300 and not epitaxially grown. On the other hand, an average grain size of the channel material 306 being equal to or greater than about 1 millimeter (in which case the material may be considered to be a single-crystalline material) may be indicative of the channel material 306 having been included in the IC device 300 by layer transfer. In the embodiments where the channel material 306 is a single-crystalline semiconductor material, it may include any of the materials described above that may be provided in a single-crystalline form.

As described above, S/D regions 308 may be regions of doped semiconductors, e.g., regions of a doped channel material, so as to supply charge carriers for the transistor channel. The S/D regions 308 may generally be formed using either an implantation/diffusion process or an etching/deposition process. In the former process, dopants such as boron, aluminum, antimony, phosphorous, or arsenic may be ion-implanted into the channel material to form the S/D regions 308 in the channel material 306. An annealing process that activates the dopants and causes them to diffuse further into the channel material 306 typically follows the ion implantation process. In the latter process, the channel material 306 may first be etched to form recesses at the locations of the S/D regions 308. An epitaxial deposition process may then be carried out to fill the recesses with material that is used to fabricate the S/D regions 308. In some implementations, the S/D regions 308 may be fabricated using a silicon alloy such as silicon germanium or silicon carbide. In some implementations the epitaxially deposited silicon alloy may be doped in situ with dopants such as boron, arsenic, or phosphorous. In further embodiments, the S/D regions 308 may be formed using one or more alternate semiconductor materials such as germanium or a group III-V material or alloy. And in further embodiments, one or more layers of metal and/or metal alloys may be used to form the S/D regions 308.

The gate insulator material 310 is provided between the gate electrode material 304 and the channel material 306. In some embodiments, the gate insulator material 310 may be a high-k dielectric material typically used in logic transistors and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric material of the IC device 300 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, scandium aluminum nitride, tantalum oxide, tantalum silicon oxide, lead scandium tantalum oxide, and lead zinc niobate. In some embodiments, an annealing process may be carried out on the gate dielectric material during manufacture of the IC device 300 to improve the quality of the gate dielectric. In some embodiments, the gate dielectric included in the gate stack of the transistor 320 may have a thickness between about 0.5 nanometers and 3 nanometers, including all values and ranges therein, e.g., between about 1 and 3 nanometers, or between about 1 and 2 nanometers. In some embodiments, the gate insulator material 310 may include the hysteretic element 135 as described above, instead of, or in addition to, a high-k dielectric material as used in logic transistors.

Although also not shown in the present drawings, in some embodiments of the IC device 300, the transistor 320 may further include an intermediate material between at least a portion of the gate insulator material 310 and at least a portion of the channel material 306. Such an intermediate material may include any non-conductive material, and may be provided to address endurance issues that may arise due to charging at the interface between the gate insulator material 310 and the channel material 306 that may take place if the gate insulator material 310 directly interfaces the channel material 306.

The insulator material 312 may include any suitable interlayer dielectric (ILD) material for providing electrical isolation between portions of the IC device 300. In various embodiments, the insulator material 312 may include materials such as silicon oxide, carbon-doped silicon oxide, silicon carbide, silicon nitride, silicon oxynitride, aluminum oxide, organic polymers such as perfluorocyclobutane or polytetrafluoroethylene, fluorosilicate glass (FSG), and organosilicates such as silsesquioxane, siloxane, or organosilicate glass. In some embodiments, the insulator material 312 may be a low-k dielectric. In some embodiments, the insulator material 312 may include pores or air gaps to further reduce its dielectric constant. The spacer material 314 may also include any such ILD material for providing electrical isolation between the wordline 350 and the channel material 306.

Turning to the details of the vertical nature of the transistor 320, as shown in FIGS. 3A and 3C, each of the channel material 306 and the gate insulator material 310 includes portions that may be referred to as “sidewall portions” because they are substantially perpendicular to the support structure 302. As further shown in FIGS. 3A and 3C, each of the channel material 306 and the gate insulator material 310 includes a portion that may be referred to as a “middle horizontal portion” because it is in between the sidewall portions (i.e., in the middle) and is substantially parallel to the support structure 302 (such a portion may also be referred to as a “bottom portion” or, simply, a “bottom” because it is at the bottom of the opening in the insulator material 312, i.e., closest to the support structure 302). The first and second sidewall portions of the channel material 306 are labeled in FIG. 3A as, respectively, portions 316-1 and 316-2, and the middle horizontal portion of the channel material 306 is labeled in FIG. 3A as a portion 316-3. Similarly, the first and second sidewall portions of the gate insulator material 310 are labeled in FIG. 3A as, respectively, portions 322-1 and 322-2, and the middle horizontal portion of the gate insulator material 310 is labeled in FIG. 3A as a portion 322-3. As shown in FIG. 3A, the middle horizontal portion 322-3 is between the middle horizontal portion 316-3 and the gate electrode material 304, the first sidewall portion 322-1 is between the first sidewall portion 316-1 and the gate electrode material 304, and the second sidewall portion 322-2 is between the second sidewall portion 316-2 and the gate electrode material 304.

The different portions 316 of the channel material 306 form a continuous layer of the channel material 306, starting from the first sidewall portion 316-1, continuing with the middle horizontal portion 316-3, and further continuing with the second sidewall portion 316-2. Thus, a continuous channel region is provided between the first S/D region 308-1 and the second S/D region 308-2. Similarly, the different portions 322 of the gate insulator material 310 form a continuous layer of the gate insulator material 310, starting from the first sidewall portion 322-1, continuing with the middle horizontal portion 322-3, and further continuing with the second sidewall portion 322-2. Thus, the gate insulator material 310 is provided continuously along the channel material 306, between the channel material 306 and the gate electrode material 304, where the channel material 306 may be conformal to the shape of the gate insulator material 310.

As shown in FIGS. 3A and 3C, the gate insulator material 310 is non-planar in that it includes bends/corners. In particular, each of the gate insulator material 310 and the channel material 306 of the IC device 300 may be seen as a U-shaped structure. The IC device 300 may then be described as having a gate that includes a U-shaped structure of the gate insulator material 310. Because the channel material 306 is conformal to the shape of the gate insulator material 310, the channel material 306 is non-planar as well and includes bends/corners corresponding to those of the gate insulator material 310. In regions where the gate insulator material 310 bends (i.e., at the corners of the gate insulator material 310), the electric field may be higher and, therefore, it may be easier to switch the memory state of the gate insulator material 310 if the gate insulator material 310 includes the hysteretic element 135.

The transistor 320 as shown in FIGS. 3A-3C is a vertical transistor because the first S/D contact, provided by one of the control lines (e.g., the plateline 360) is at the bottom of the transistor 320 (i.e., closer to the support structure 302), while the second S/D contact, provided by another one of the control lines (e.g., the bitline 340) is proximate to the top of the transistor 320 (i.e., further away from the support structure 302). Such a vertical transistor architecture may enable increasing the effective gate length (Leff) of the transistor 320 without substantially increasing its footprint over the support structure 302. Increased effective gate length may help reduce device-to-device variations and decrease the current in the off-state (Ioff) of the transistor (i.e., leakage current). Furthermore, as can be seen from the top-down cross-section of FIG. 3B, one of the control lines that is proximate to the top of the transistor 320 (e.g., the bitline 340) may wrap-around the opening in the insulator material 312 in which the transistor 320 is provided, enabling lower contact resistance and resulting in higher currents.

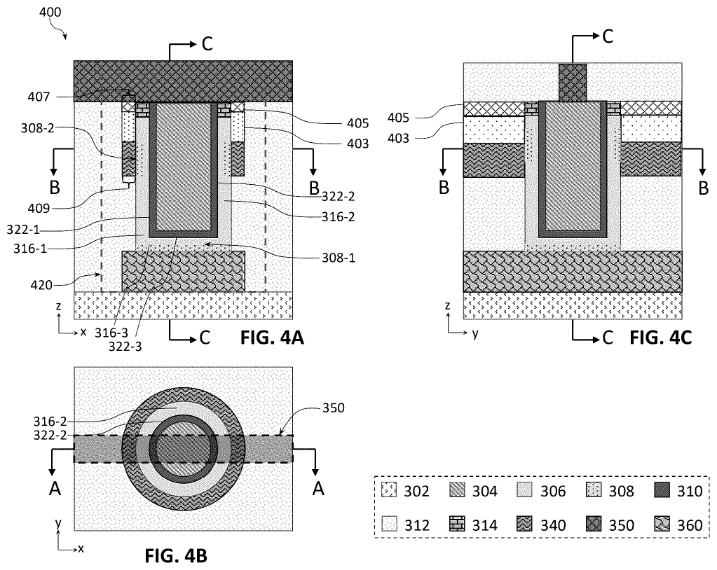

As explained in further detail below, in one example, a method of fabricating an IC device with an array of memory cells and a merged control line involves providing a sacrificial material over a layer of conductive material (e.g., over a conductive bitline material) and etching the conductive material in areas not covered by the sacrificial material. In one such example, the width of the sacrificial material is sufficiently large to enable the sacrificial material between closely-spaced adjacent memory cells to merge, thus causing the conductive material for the control line coupled with those adjacent memory cells to be merged. When such a sacrificial material is used to form an IC device with merged control lines, the sacrificial material may be present or absent in the final IC device. FIGS. 3A-3C illustrate an example IC device 300 in which a sacrificial material is absent in the final IC device. FIGS. 4A-4C provide various views of another example IC structure 400 in which a sacrificial material is present.

FIGS. 4A-4C illustrate an example IC structure 400 that may be used to implement a hysteretic memory cell 100 of FIG. 1A with a vertical transistor 420 and merged control lines. The IC structure 400 of FIGS. 4A-4C includes elements similar to those in the IC device 300 of FIGS. 3A-3C (e.g., a support structure 302, a channel material 306, a gate electrode material 304, etc.), and further includes a sacrificial material 405 in a layer between the bitline 340 and the wordline 350. In the example illustrated in FIG. 4A, the IC structure 400 also includes a layer of an insulator material 403 between the sacrificial material 405 and the bitline 340. In one example, the sacrificial material may include any suitable sacrificial material such as a hard mask material (e.g., an oxide or nitride-based material, amorphous silicon, a metallic material such as titanium nitride or tantalum nitride, or any other suitable mask/sacrificial material), or other suitable sacrificial material. The insulator material 403 may be any suitable insulator material, such as the ILDs mentioned above. The insulator material 403 may be the same as or different from the insulator material 312 surrounding the memory cell.

In one example, the memory cell includes the sacrificial material 405 around sidewalls of the opening in which the memory cell is formed (e.g., around the first sidewall portion 316-1 and around the second sidewall portion 316-2 of the channel material 306). In one example, the sacrificial material 405 is used as a mask to enable portions of the bitline material between closely-spaced memory cells to merge, and therefore the width of the sacrificial material 405 is about the same as the width of the bitline 340, where the width of the sacrificial material 405 is a dimension of the sacrificial material in a plane substantially parallel to the support structure 302 (e.g., along the x-axis as shown in FIG. 4A). For example, consider that the bitline 340 includes a portion 409 of a continuous conductive material between the sidewalls of the opening and the insulator material 312, and that the portion 409 has a first width that is a dimension of the portion 409 in a first plane substantially parallel to the support structure 302 (e.g., along the x-axis). In this example, the sacrificial material also includes a portion 407 between the sidewalls of the opening and the insulator material 312 (e.g., directly over the portion 409), where the portion 407 of the sacrificial material 405 has a second width which is a dimension of the portion 407 in a second plane substantially parallel to the support structure 302, and where the second width is about the same as the first width.

Thus, in the example illustrated in FIG. 4A, the IC structure 400 includes the sacrificial material 405 around and/or on sidewalls of the opening in a layer between a first control line (e.g., the bitline 340) and a second control line (e.g., the wordline 350). In other examples, the sacrificial material 405 may be absent regardless of whether the sacrificial material 405 was used in the processes of forming an IC structure with a merged control line. For example, even if the sacrificial material 405 was used to form merged control lines, the sacrificial material 405 may be removed in a subsequent processing step so that it is absent in the final IC structure.

The transistor 320 of FIGS. 3A-3C and the transistor 420 of FIGS. 4A-4C are examples of hysteretic transistors. In other examples, the transistors used to implement memory cells may be non-hysteretic transistors (e.g., the gate insulator may be a conventional gate dielectric material that does not have hysteretic properties). In one such example, the transistors as described herein may be coupled to capacitors which may be hysteretic capacitors.

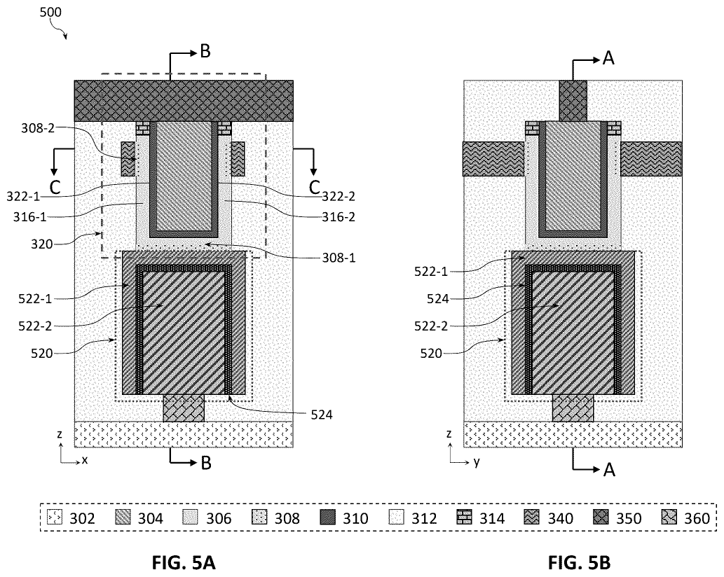

One such example implementation is shown in FIGS. 5A-5B, providing various views of an example IC device 500 implementing a memory cell with a vertical transistor 320 and a capacitor 520, according to some embodiments of the present disclosure. The IC device 500 is similar to the IC device 300 in that it includes the vertical transistor 320 as described above. In particular, FIG. 5B illustrates a cross-section of the IC device 500 taken along the section/plane B-B of FIG. 5A, which is similar to the cross-section along the plane C-C of FIG. 3A, shown in FIG. 3C, while FIG. 5A illustrates a cross-section of the IC device 500 taken along the section/plane A-A of FIG. 3B, which is similar to the cross-section along the plane A-A of FIGS. 3B and 3C, shown in FIG. 3A. A cross-section similar to that shown in FIG. 3B is not shown in FIG. 5 because for the IC device 500 such a cross-section would look the same as that shown in FIG. 3B.

The differences between the IC device 500 and the IC device 300 arise in the presence of the capacitor 520 in the IC device 500, where a portion of the IC device 500 within a rectangular dotted contour shown in FIGS. 5A-5B indicates an approximate outline of the capacitor 520. As shown in FIGS. 5A-5B, the capacitor 520 includes a first capacitor electrode 522-1, a second capacitor electrode 522-2, and a capacitor insulator 524 between the first and second capacitor electrodes 522. More specifically, the first capacitor electrode 522-1 may be electrically coupled to (e.g., in conductive contact with) the first S/D region 308-1 at the bottom of the transistor 320. The plateline 360 may then be coupled to the second capacitor electrode 522-2, at the bottom of the second capacitor electrode 522-2, as shown in FIGS. 5A-5B.

In some embodiments, the capacitor 520 may be a three-dimensional metal-insulator-metal capacitor as shown in FIGS. 5A-5B, e.g., provided in an opening in the insulator material 312. In some embodiments, the first and second capacitor electrodes 522 may include any of the electrically conductive materials as described herein. In other embodiments, at least one of the first and second capacitor electrodes 522 may include any of the semiconductor materials as described herein. The capacitor insulator 524 may include the hysteretic element 135 as described above, instead of, or in addition to, a dielectric material as used in conventional, non-hysteretic, capacitors.

Another example implementation where the transistor 320 as described herein is coupled to a capacitor that may be a hysteretic capacitor is shown in FIGS. 6A-6B, providing various views of an example IC device implementing a memory cell with a vertical transistor 320, a wrap-around bitline 340, and a capacitor 520, according to other embodiments of the present disclosure. The IC device 600 is similar to the IC device 500 in that it includes the vertical transistor 320 as described above and the vertical transistor 320 is coupled to a capacitor 520 that includes a first capacitor electrode 522-1, a second capacitor electrode 522-2, and a capacitor insulator 524 between the first and second capacitor electrodes 522. In particular, FIG. 6B illustrates a cross-section of the IC device 600 taken along the section/plane B-B of FIG. 6A, which is similar to the cross-section shown in FIG. 5B, while FIG. 6A illustrates a cross-section of the IC device 600 taken along the section/plane A-A of FIG. 3B, which is similar to the cross-section shown in FIG. 5A.

The differences between the IC device 600 and the IC device 500 is in the orientation of the capacitor 520. In particular, the capacitor 520 shown in FIGS. 6A-6B is substantially upside down compared to the capacitor 520 shown in FIGS. 5A-5B. As a result, in the IC device 600, it is the second capacitor electrode 522-2 that is electrically coupled to (e.g., in conductive contact with) the first S/D region 308-1 at the bottom of the transistor 320, while the plateline 360 may then be coupled to the first capacitor electrode 522-1, at the bottom of the first capacitor electrode 522-1, as shown in FIGS. 6A-6B.

While FIGS. 5A-5B and FIGS. 6A-6B are described with reference to the capacitors 520 being hysteretic capacitors, in other embodiments, the capacitor 520 of the IC devices 500 or 600 may be a non-hysteretic capacitor, while the transistor 320 of these IC devices may be a hysteretic transistor, all of which embodiments being within the scope of the present disclosure.

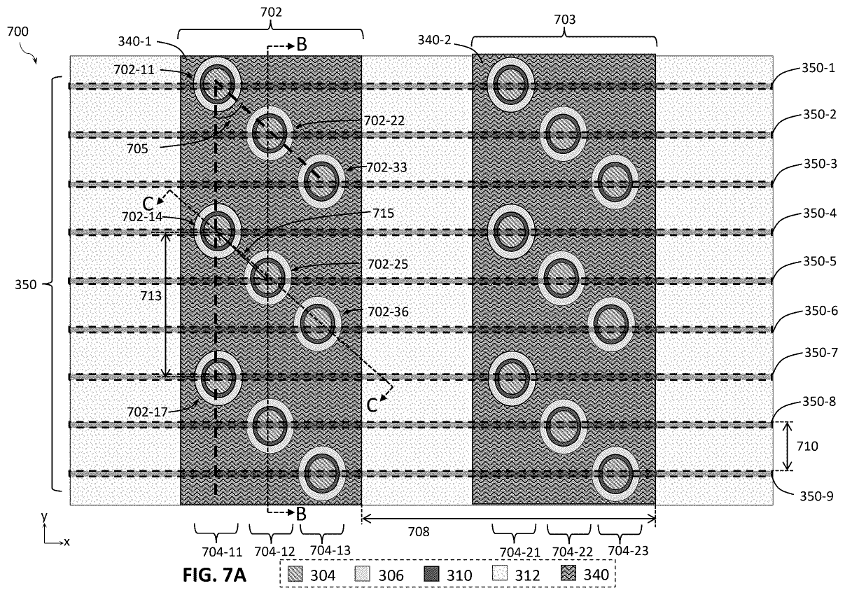

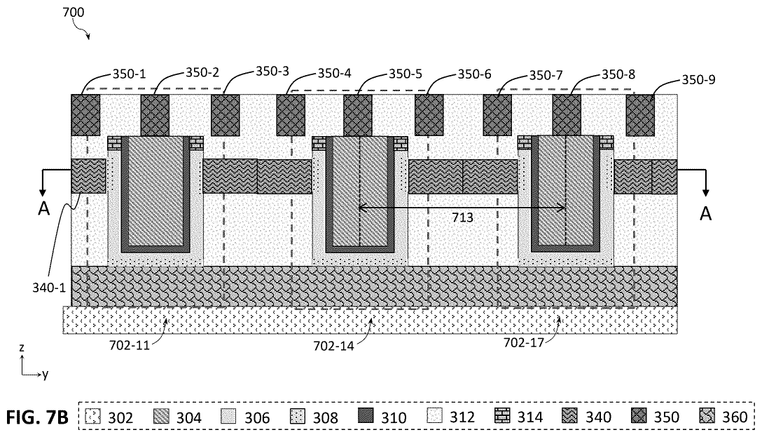

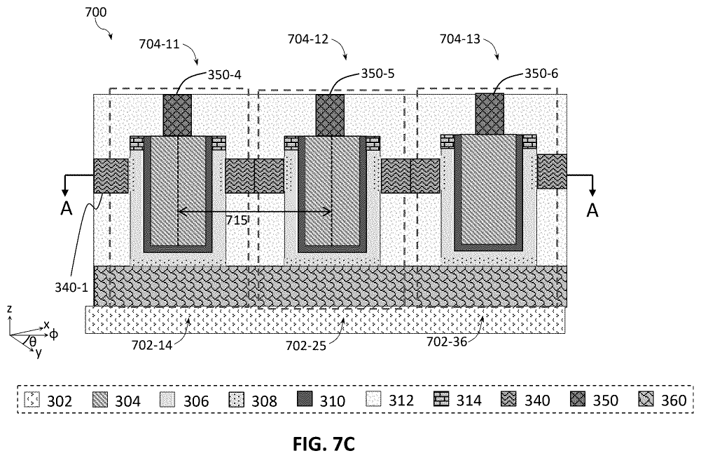

FIGS. 7A-7C, and 8-13 provide various views of example IC devices implementing an array of memory cells with vertical transistors and merged control lines. FIGS. 7A and FIGS. 8-13 illustrate top-down views of arrays of memory cells across an x-y plane, with a number of components not shown in the top-down view in order to more readily illustrate arrangements of memory cells with respect to bitlines and wordlines. FIG. 7B illustrates a cross-sectional view taken along the plane B-B of FIG. 7A, e.g., along the z-y plane. FIG. 7C illustrates a cross-section view taken along a plane C-C of FIG. 7A.

Turning first to FIG. 7A, the IC device 700 includes an array of memory cells, which includes a first plurality of memory cells 702 and a second plurality of memory cells 703, where the first plurality of memory cells 702 is coupled with a first bitline 340-1, and the second plurality of memory cells 703 is coupled with a second bitline 340-2. The plurality of memory cells 702 is arranged or oriented in lines 704-11, 704-12, 704-13 that are staggered with respect to one another, where the lines 704-11, 704-12, 704-13 are substantially parallel to the support structure over which they are disposed and parallel to the length of the bitline 340-1 (e.g., along the y-axis as illustrated in FIG. 7A). In one example, the lines are staggered with respect to one another in a same plane over the substrate, where the plane is substantially parallel to the substrate. The IC device 700 also includes a plurality of wordlines 350. In the example of FIG. 7A, the lines 704-11, 704-12, 704-13 of memory cells are substantially parallel with respect to one another, and substantially orthogonal to the wordlines 350. In the example illustrated in FIG. 7A, the memory cells coupled to the same bitline 340-1 in adjacent lines (e.g., in an adjacent pair of the lines 704-11, 704-12, 704-13) are offset from one another along the y-axis (e.g., along an axis parallel to the length of the bitline 340-1), enabling each one of the memory cells 702 to be coupled with a different one of the wordlines 350. Similarly, the plurality of memory cells 703 is arranged or oriented in lines 704-21, 704-22, 704-23 that are staggered with respect to one another, where the lines 704-21, 704-22, 704-23 are substantially parallel to the support structure over which they are disposed and parallel to the length of the bitline 340-2. Thus, the plurality of memory cells 703 is also arranged in lines 704-21, 704-22, 704-23 that are staggered with respect to one another such that each of the memory cells 703 is coupled with a different one of the wordlines 350. Accordingly, in the example illustrated in FIG. 7A, only one bitline and one wordline intersect with a memory cell of the array.

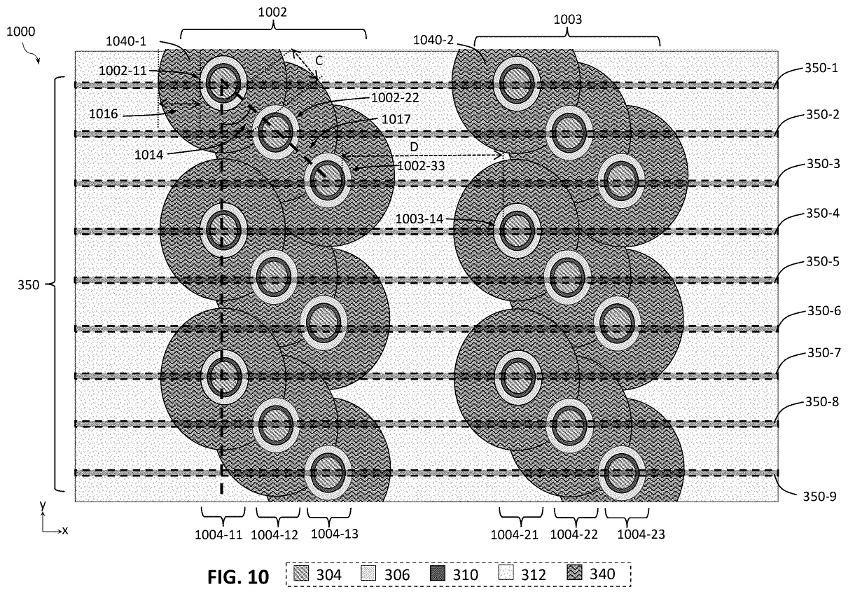

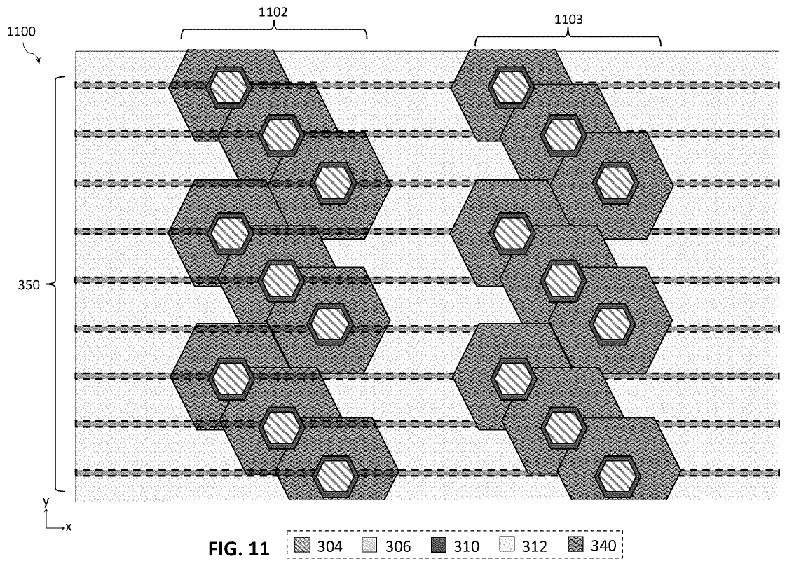

In one example, the first bitline 340-1 and the second bitline 340-2 are each a merged control line in the sense that there is a continuous conductive control line material between adjacent memory cells coupled with the respective bitline. For example, the bitline 340-1 includes a continuous volume or continuous portion of conductive material between the memory cell 702-11 (e.g., a first memory cell of a first line 704-11) and the memory cell 702-22 (e.g., a second memory cell of a second line 704-12, where the second memory cell is a nearest neighboring memory cell of the second line 704-12 to the first memory cell 702-11). Similarly, in the example illustrated in FIG. 7A, the IC device 700 includes a continuous conductive material between the memory cell 702-22 and the memory cell 702-33. In the example illustrated in FIG. 7A, there is also a continuous conductive material between adjacent memory cells in the same line (e.g., there is a continuous conductive material between the memory cell 702-11 and the memory cell 702-14, which is adjacent to the memory cell 702-11 in the line 704-11). Thus, the bitline material between adjacent memory cells of the plurality of memory cells 702 is merged together, and the bitline material between adjacent memory cells of the plurality of memory cells 703 is merged together. For simplicity of illustration, the bitlines 340-1, 340-2 are illustrated in FIG. 7A as having straight outer edges (e.g., sides of the bitlines 340-1, 340-2 that extend along the respective lengths of the bitlines), however, merged bitlines may have non-straight outer edges. For example, a merged bitline may include portions of a conductive material around each of the memory cells, where those portions are merged together to form a continuous portion of conductive material. Thus, in one example, a merged bitline may have outer edges that are not straight, and which may conform to the shape of the memory cells around which the bitline material is disposed. FIGS. 10-12, which are discussed below, illustrate examples of IC devices including merged bitlines with non-straight outer edges.

In the example illustrated in FIG. 7A, the lines 704-21, 704-22, 704-23 of memory cells are separated by a distance and staggered such that an angle 705 between the bitline 340-1 and a line connecting the centroids of neighboring memory cells in adjacent lines is less than 60 degrees. In examples described herein, the term “centroid of a memory cell” is used in the context of the centroid of another neighboring memory cell, and is used as a way to describe the location of the memory cell in relation to the neighboring memory cell. A centroid is a geometric center of a plane shape. For example, the centroid of a triangle is the point of concurrency of three medians of the triangle. In another example, the centroid of a circle is the center of the circle. The centroid of a rectangle is at the point that the two diagonals of the rectangle intersect. The centroid of other shapes may be determined as the approximate geometric center of the shape. In one example, the centroid of a memory cell is the approximate geometric center of the cross-sectional shape of a memory cell along a plane that is substantially parallel with the substrate. The exact plane along which the centroids of the two neighboring memory cells are determined may not be important as long as the centroids are determined or calculated in the same way for each of the neighboring memory cells. For example, in an array of memory cells, where the memory cells are different instances of the same type of memory cell, each of the memory cells in the array may have approximately the same cross-sectional shape in a plane that is substantially parallel to the substrate, and therefore the centroid (e.g., geometric center) of the cross-sectional shape of each of those memory cells may be determined according to the same geometric principal. For example, if the cross-sectional shape of the memory cells along a plane substantially parallel to the substrate is a circle (e.g., approximately circular), then the centroid of those memory cells may be taken as the center of the circular cross-section of those memory cells.

Referring again to FIG. 7A, a line between the centroid of the memory cell 702-11 and the centroid of the memory cell 702-22 is at the angle 705 relative to the bitline 340-1. In one example, the angle 705 is in a range of about 30-60 degrees, 30-55, or 35-55 degrees. Other angles are possible depending on implementation. For example, the angle 705 may be in a range of about 20-70 degrees. In one such example, an angle of greater than 60 degrees (e.g., 60-70 degrees) may be achieved with memory cells having an elongated/oblong (e.g., oval) shaped cross-section. Thus, in one example, the distance between the centroids of neighboring memory cells in the same line (e.g., in one of the lines 704-11, 704-12, 704-13) is greater than the distance between the centroids of neighboring cells in adjacent lines. For example, the distance 713 between the centroid of the memory cell 702-14 and the centroid of the memory cell 702-17 is greater than the distance 715 between the centroid of the memory cell 702-14 and the centroid of the memory cell 702-25. In one example, if the memory cells are laid out such that there is an angle of 60 degrees (e.g., if the memory cells are laid out in an equilateral triangle), the equilateral triangle layout limits the control line pitch and therefore limits the number of staggered lines of memory cells that can be arranged to couple with a common bitline. In contrast, in one example, when the angle 705 is less than 60 degrees, more than two staggered lines of memory cells can be arranged to share a common bitline and separate wordlines, which can enable increasing the overall memory cell density in the array. Although FIG. 7A depicts a plurality of memory cells 702 arranged in three lines 704-11, 704-12, 704-13, in other examples, memory cells sharing a common bitline may be arranged in two staggered lines, four staggered lines, or more than four staggered lines.

In one example, arranging the plurality of memory cells 702 so that the angle 705 is smaller than 60 degrees enables flexibility in the control line pitch. For example, a shallower angle between the bitline and a line connecting the centroids of neighboring memory cells in adjacent lines enables a narrow wordline pitch and a significantly wider bitline pitch. In the example illustrated in FIG. 7A, the bitlines 340-1, 340-2 have a first pitch 708 and the wordlines 350 have a second pitch 710 that is smaller than the first pitch 708. In the example illustrated in FIG. 7A, the pitch 710 of the wordlines is approximately equal to the distance along the y-axis (e.g., along the axis parallel to the length of the bitline 340-1) between the centroid of the memory cell 702-11 in the first line 704-11 and the centroid of the nearest neighboring memory cell 702-22 in the second line 704-12 that is adjacent to the first line 704-11. In the example illustrated in FIG. 7A, the pitch 708 of the bitlines is larger than the pitch 710.

FIG. 7B shows another cross-sectional view of the IC device 700 along the z-y plane. As can be seen in FIG. 7B, the memory cells 702-11, 702-14, and 702-17 are coupled with the same merged bitline 340-1. In the example illustrated in FIG. 7B, each of the memory cells 702-11, 702-14, and 702-17 are coupled with a different wordline. Specifically, the memory cell 702-11 is coupled with the wordline 350-2, the memory cell 702-14 is coupled with the wordline 350-5, and the memory cell 702-17 is coupled with the wordline 350-8. The memory cells 702-11, 702-14, and 702-17 are in the same line 704-12 that is substantially parallel to the length of the bitline 340-1. In the example in FIGS. 7A-7B there are three such lines of memory cells that are staggered relative to one another and coupled with the bitline 340-1, and therefore FIG. 7B depicts two wordlines between each of the illustrated memory cells that are coupled with memory cells in the other lines (which are not visible in the cross-sectional view of FIG. 7B). For example, the wordline 350-1 is coupled with the memory cell 702-11 in the line 704-11 adjacent to the line 704-12. Although only three memory cells 702-11, 702-14, and 702-17 are depicted in FIG. 7B for ease of illustration, a typical memory device will include more than three memory cells in a given one of the lines 704-11, 704-12, 704-13 of memory cells.

FIG. 7C shows another cross-sectional view of the IC device 700 along a plane that intersects the three lines 704-11, 704-12, 704-13 of memory cells (e.g., along the z-ϕ plane, where ϕ is shown to be at an angle of θ with respect to the y-axis, where θ is representative of the angle 705 of FIG. 7A). The example in FIG. 7C illustrates neighboring memory cells 702-14, 702-25, 702-36 in three lines 704-11, 704-12, 704-13 of memory cells that are coupled with the same merged bitline 340-1. As can be seen in FIG. 7C, the distance between the centroid of the memory cell 702-14 in the line 704-11 and the centroid of the nearest neighboring memory cell 702-25 in the adjacent line 704-12 is indicated by the distance 715, which is less than the distance 713 between centroids of adjacent memory cells in the same line.

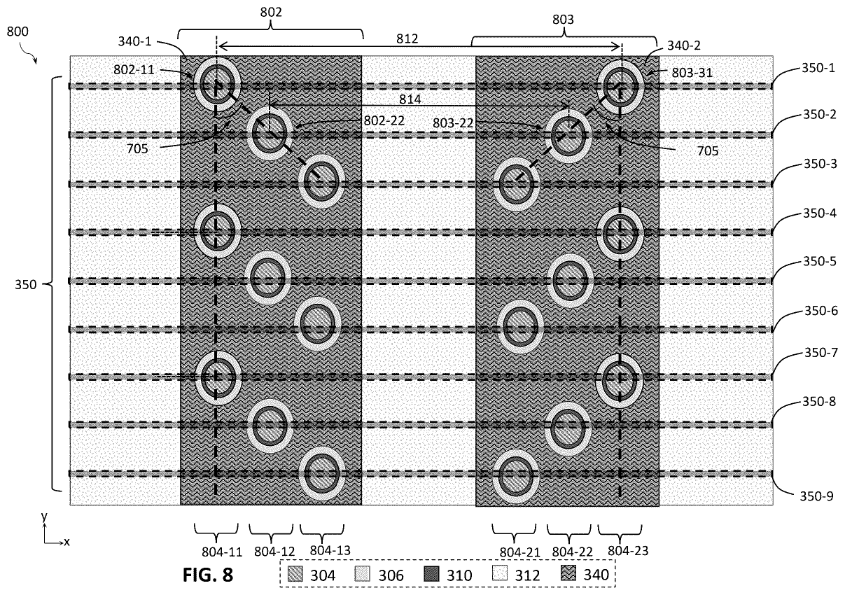

FIGS. 7A-7C illustrate examples in which the first plurality of memory cells 702 and the second plurality of memory cells 703 have approximately the same arrangement (e.g., the memory cells are arranged in lines that are staggered in a similar fashion). However, it is also possible for memory cells coupled with different bitlines to have different arrangements. For example, FIG. 8 illustrates an example in which one plurality of memory cells 802 that is coupled with a first bitline 340-1 has a mirrored arrangement relative to another plurality of memory cells 803 that is coupled with a second bitline 340-2. Like the IC device 700 of FIG. 7A, the IC device 800 of FIG. 8 includes a first plurality of memory cells 802 that are arranged in three lines 804-11, 804-12, 804-13, which are staggered with respect to one another, and a second plurality of memory cells 803 that are arranged in three lines 804-21, 804-22, 804-23, which are staggered with respect to one another. However, the IC device 800 of FIG. 8 differs in how the staggered lines of memory cells coupled with a given bitline are arranged. Specifically, in the example illustrated in FIG. 8, the lines of memory cells 803 are staggered in an opposite order compared to the lines of memory cells 802, such that the top-down cross-sectional view of FIG. 8 has a mirrored appearance about a line parallel with the y-axis between the bitlines 340-1, 340-2.

In one example, due to the opposite or mirrored staggering arrangement of the memory cells, the distance between memory cells coupled with the same wordline (but different bitlines) varies depending on which wordline the memory cells are coupled to. For example, consider that the plurality of wordlines 350-1-350-9 includes a first wordline 350-1 and a second wordline 350-2 adjacent to the first wordline 350-1. The memory cell 802-11 of the first plurality of memory cells 802 and the memory cell 803-31 of the second plurality of memory cells 803 are coupled with the first wordline 350-1 and separated by a first distance 812 (e.g., the distance between the centroid of the memory cell 802-11 and the centroid of the memory cell 803-31 is the distance 812 as shown in FIG. 8). In this example, the memory cell 802-22 of the first plurality of memory cells 802 and the memory cell 803-22 of the second plurality of memory cells 802 are coupled with the second wordline 350-2 and separated by a second distance 814 (e.g., the distance between the centroid of the memory cell 802-22 and the centroid of the memory cell 803-22 is the distance 814 as shown in FIG. 8), where the distance 812 is different from (e.g., greater than) the distance 814.

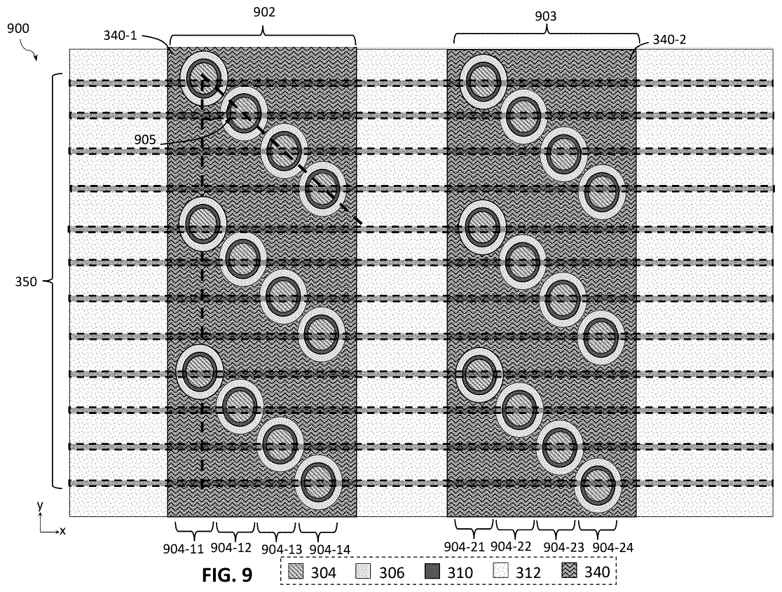

Thus, FIGS. 7A-7C and 8 illustrate examples of memory cells coupled with a merged bitline that are arranged in three staggered lines, where the bitline includes a continuous conductive material between neighboring memory cells of the adjacent lines of memory cells. In other examples, the memory cells coupled with a merged control line may have different arrangements (e.g., one line, two lines, or more than three lines). FIG. 9 illustrates a top-down cross-sectional view of an IC device 900 implementing an array of a plurality of memory cells with vertical transistors and merged control lines, where the memory cells coupled with a bitline are arranged in four staggered lines. The example in FIG. 9 includes a first plurality of memory cells 902 arranged in four lines 904-11, 904-12, 904-13, 904-14, which are staggered relative to one another. Similarly, the IC device includes a second plurality of memory cells 903 that are arranged in four lines 904-21, 904-22, 904-23, 904-24, which are staggered with respect to one another. The first plurality of memory cells 902 is coupled with the bitline 340-1 and the second plurality of memory cells 903 is coupled with the bitline 340-2. In one example, similar to the three-line arrangement discussed above, the angle 905 between the bitline 340-1 and a line connecting the centroids of neighboring memory cells in adjacent lines is less than 60 degrees. In one example, coupling four adjacent lines of memory cells with the same bitline is in part enabled with an angle 905 that is shallower than 60 degrees, as shown in FIG. 9.

FIGS. 7A, 8, and 9 illustrate IC devices with bitlines having straight edges, however, a memory device fabricated with technique for forming merged control lines may have non-straight edges that may approximately conform to the shape of the memory cells. For example, FIGS. 10-12 illustrate example IC devices having memory cells with different cross-sectional shapes and merged control lines.

Turning first to FIG. 10, the IC device 1000 includes a plurality of memory cells 1002 coupled with the bitline 1040-1, and a plurality of memory cells 1003 that are coupled with the bitline 1040-2. The bitlines 1040-1 and 1040-2 are examples of the bitlines 340, discussed above. Like the IC device 700 of FIG. 7A, the IC device 1000 includes three lines 1004-11, 1004-12, 1004-13 of memory cells that are coupled with the bitline 1040-1, and three lines 1004-21, 1004-22, 1004-23 of memory cells that are coupled with the bitline 1040-2. The bitline 1040-1 includes portions of conductive material surrounding each of the memory cells 1002, where the portions are merged together between adjacent closely-spaced memory cells to form a continuous conductive material of the bitline 1040-1. Similarly, the bitline 1040-2 includes portions of conductive material surrounding each of the memory cells 1003, where the portions are merged together to form a continuous conductive material of the bitline 1040-2. For example, the bitline 1040-1 includes a continuous layer or portion 1014 of conductive material between a first memory cell 1002-11 of a first line 1004-11 and a second memory cell 1002-22 of a second line 1004-12, where the second memory cell 1002-22 is a nearest neighboring memory cell of the second line 1004-12 to the first memory cell 1002-11. In the example illustrated in FIG. 10, there is also a continuous portion 1017 of a conductive material between the second memory cell 1002-22 and a third memory cell 1002-33 of a third line 1004-13. In one example, the individual memory cells include a semiconductor material (e.g., the channel material 306) on sidewalls of the openings in which the memory cells are formed, and the continuous conductive material of the bitline is in contact with the semiconductor material of the adjacent memory cells coupled with the same bitline. For example, the continuous portion 1014 of conductive material is on contact with the channel material 306 of the memory cell 1002-11 and in contact with the channel material 306 of the memory cell 1002-22.

In one example, the continuous portions 1014 and 1016 are formed by the merging of conductive material around the adjacent memory cells. For example, the bitline at least partially wraps around the semiconductor material of the memory cells, and the width of the bitline material is large enough so that there are merged portions of the bitline between adjacent memory cells coupled with the same bitline. For example, the bitline 1040-1 has a portion of the continuous conductive material between the channel material 306 of the memory cell 1002-11 and the surrounding insulator material 312, where the portion has a width 1016 that is greater than or equal to half the distance ‘C’ between the channel material 306 of the memory cell 1002-11 and the channel material 306 of the memory cell 1002-22, where the width 1016 is a dimension of the portion of conductive material in a plane substantially parallel to the substrate. In one such example, the width 1016 is less than (D−x)/2, where ‘D’ is the distance between the channel material of an outer memory cell of the bitline 1040-1 (e.g., the memory cell 1002-33) and the channel material of a neighboring outer memory cell of an adjacent bitline 1040-2 (e.g., the memory cell 1003-14), and ‘x’ is a value in a range between about 10 nanometers and 100 nanometers. In one such example, the number ‘x’ is a buffer distance to ensure isolation between the two bitlines 1040-1, 1040-2. Thus, in the example illustrated in FIG. 10, the conductive bitline material around each of the memory cells 1102 forms a merged bitline 1040-1 that is coupled to the memory cells 1102, while the conductive bitline material around memory cells that are further away from the memory cells 1002 (e.g., the memory cell 1003-14) is isolated from the bitline 1040-1 by the insulator material 312. Accordingly, the bitline 1040-1 is coupled with the memory cells 1002 and isolated from the memory cells 1003, and the bitline 1040-2 is coupled with the memory cells 1003 and isolated from the memory cells 1002.

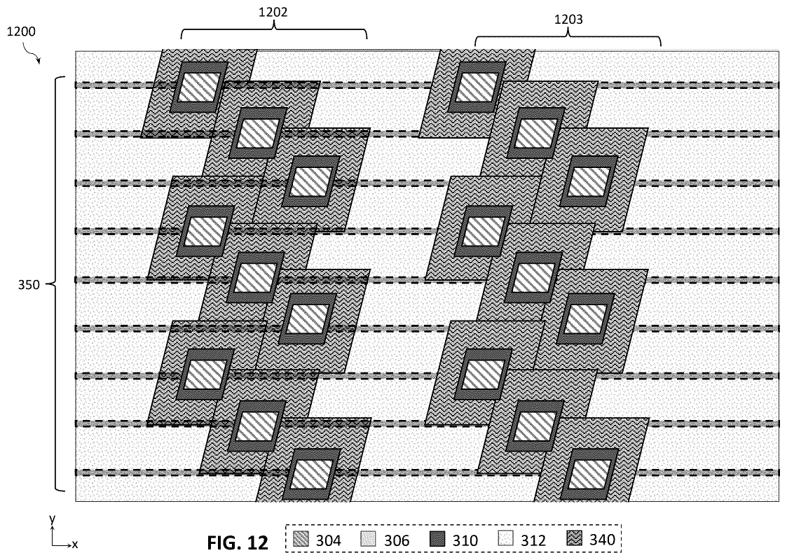

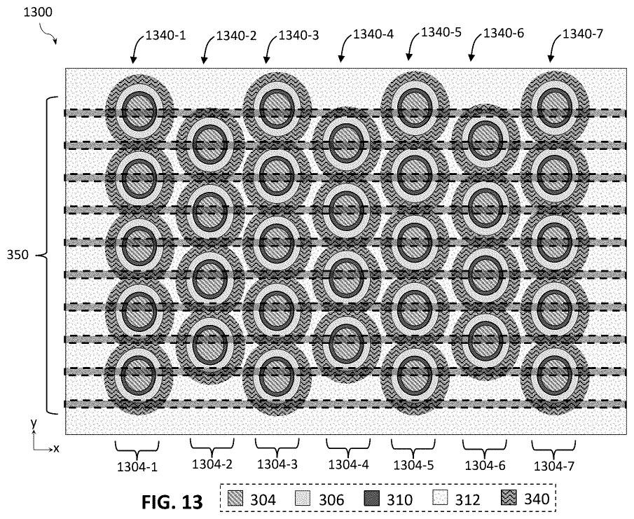

FIGS. 7A and 8-10 illustrate examples of IC devices including memory cells with a round or circular cross-section; however, IC devices with merged bitlines may be implemented with memory cells having other cross-sectional shapes. For example, FIG. 11 illustrates an IC device 1100 that includes a first plurality of memory cells 1102 and a second plurality of memory cells 1103, where each of the memory cells 1102, 1103 has a hexagonal cross-section. FIG. 12 illustrates another IC device 1200 that includes a first plurality of memory cells 1202 and a second plurality of memory cells 1203, where each of the memory cells 1202, 1203 has a parallelogram-shaped cross-section. Memory cells may have other shapes than those described herein, including memory cells with rounded or curved cross sections, or cross sections with shapes that include four or more sides or corners (e.g., hexagonal, rectangular, parallelogram-shaped, etc.).

FIGS. 7A. and 8-10 illustrate examples of IC devices that include memory cells arranged in two or more lines of memory cells that are coupled with a shared bitline. However, an IC device implementing an array of memory cells with merged control lines may include memory cells that are arranged in single lines coupled with a merged bitline. For example, FIG. 13 illustrates an example IC device 1300 that includes memory cells arranged in lines 1304-1, 1304-2, 1304-3, 1304-4, 1304-5, 1304-6, and 1304-7. Although seven lines of memory cells are shown in FIG. 13, an IC device will typically include many such lines of memory cells continuing along the x-axis as shown in FIG. 13. Similar to the IC device 700 of FIG. 7A, the IC device 1300 includes a plurality of bitlines 1340-1-1340-7 that are substantially parallel to one another and staggered with respect to one another along the y-axis as shown in FIG. 7A. Also, like the previously discussed IC devices, the bitlines 1340-1-1340-7 are substantially orthogonal to the plurality of wordlines 350. However, the IC device 1300 differs from the IC device 700 of FIG. 7A in that the memory cells are coupled with a bitline in a single line that is substantially parallel to the, rather than in lines of two, three, or more. Thus, the adjacent lines (e.g., the line 1304-1 and the line 1304-2 of memory cells) are spaced from one another by a distance that is sufficient to ensure the conductive bitline material does not merge between adjacent lines. Additionally, the angle between centroids of neighboring memory cells in one of the lines 1304-1-1304-7 and a line between the centroids of neighboring memory cells in adjacent lines is not necessarily less than 60 degrees, but may be about equal to 60 degrees, more than 60 degrees, or less than 60 degrees, depending on, e.g., the spacing between memory cells and the width of the conductive bitline material around the memory cells.

Thus, IC devices or structures having arrays of memory cells and merged control lines may have various arrangements and cross-sectional shapes, as illustrated by the examples discussed above. Although the examples of FIGS. 7A-7C and 8-13 refer to a merged bitline, the merged control line may be a control line other than the bitline (e.g., a merged plateline or a merged wordline).

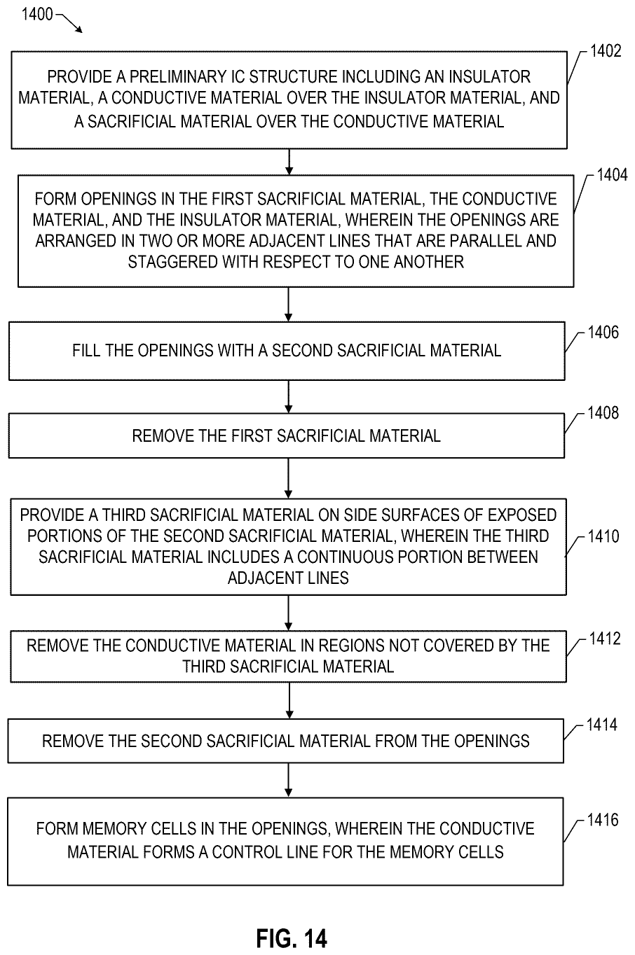

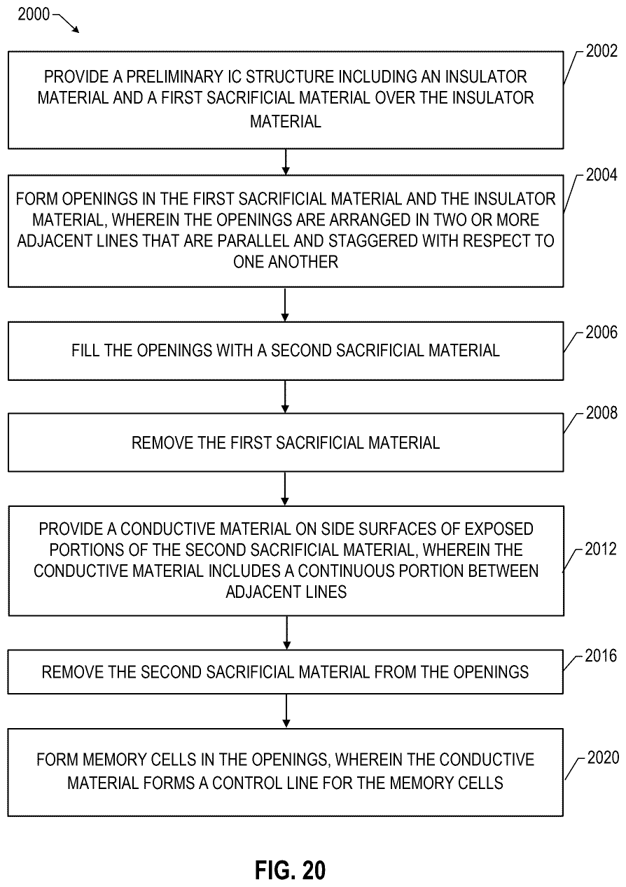

FIGS. 14 and 20 are flow diagrams of example methods for fabricating an IC device with an array of memory cells and merged control lines, in accordance with some embodiments. Although the operations of the methods of FIGS. 14 and 20 are illustrated once each and in a particular order, the operations may be performed in any suitable order and repeated as desired. For example, one or more operations may be performed in parallel to fabricate multiple IC structures using differentiated transistor isolation techniques substantially simultaneously. In another example, the operations may be performed in a different order to reflect the structure of an IC device in which memory cell arrays with merged control lines will be implemented.

In addition, the example fabricating methods of FIGS. 14 and 20 may include other operations not specifically shown in FIGS. 14 and 20, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the methods of FIGS. 14 and 20 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

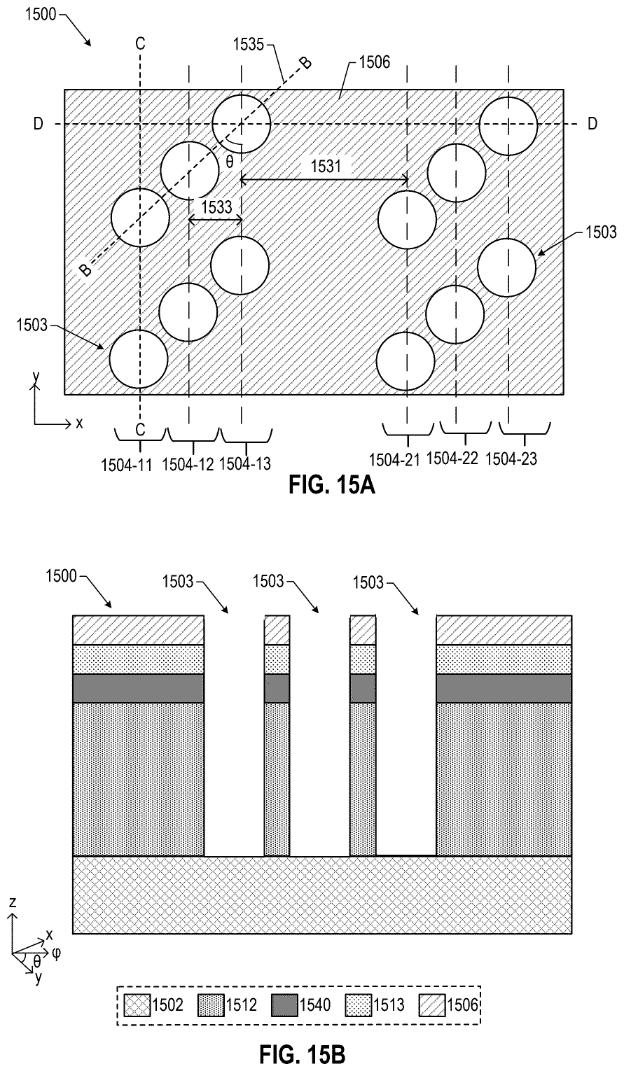

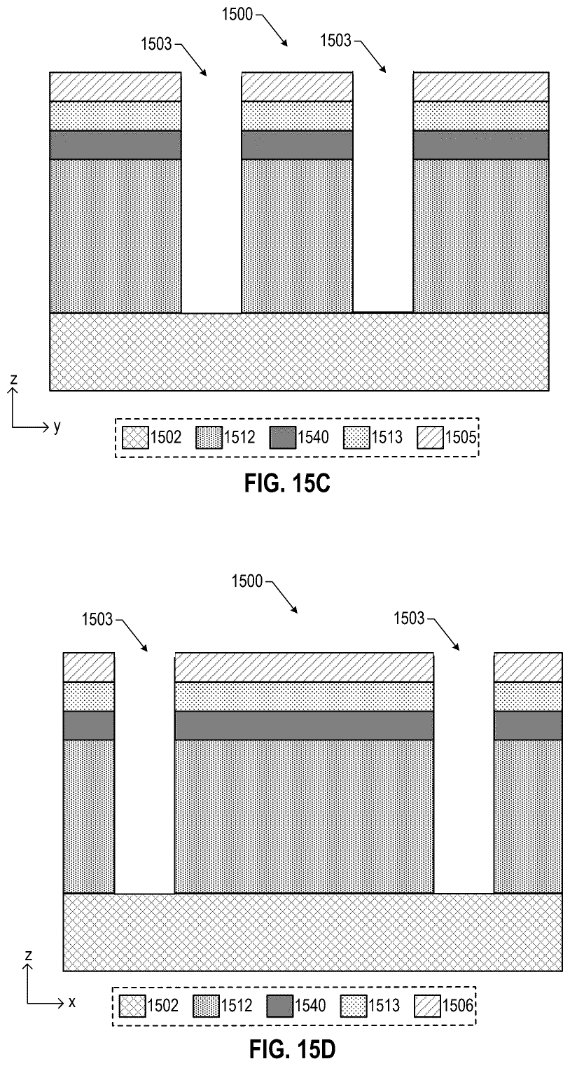

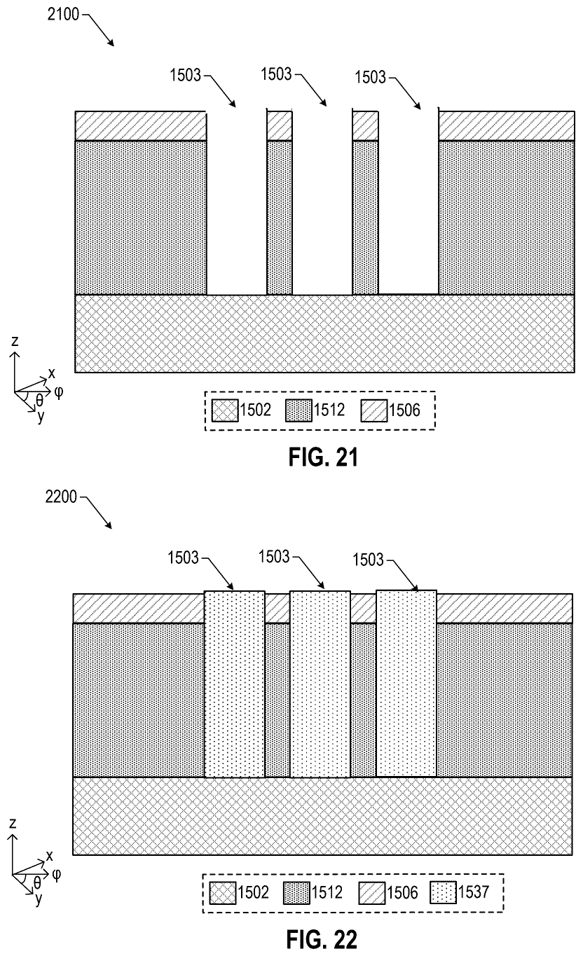

FIGS. 15A-15D, 16A-16D, 17A-17D, 18A-18D, and 19A-19D provide different views at various stages in the fabrication of an example IC structure according to the method of FIG. 14, in accordance with some embodiments. FIGS. 21-24 provide cross-sectional side views at various stages in the fabrication of an example IC structure according to the method of FIG. 20. FIGS. 15-19 include figures labeled with letters A, B, C, and D (e.g., FIG. 15 includes FIGS. 15A, 15B, 15C, and 15D), providing different views of different portions of an IC structure. In particular, those figures of FIGS. 15-19 labeled with a letter A (e.g., FIG. 15A) illustrate a top-down view of a portion of the IC structure in the x-y plane of the example coordinate system shown in other figures of the present application (e.g., FIG. 3B, 7A, etc.). Those figures of FIGS. 15-19 labeled with a letter B (e.g., 15B) illustrate a cross-sectional view of another portion of the IC structure showing a cross-sectional view along a y-o plane, as shown in the example coordinate system of FIG. 15A. Those figures of FIGS. 15-19 labeled with a letter C (e.g., 15C) illustrate a cross-sectional view of another portion of the IC structure showing a cross-sectional view along a y-z plane, as shown in the example coordinate system of FIG. 15A. Those figures of FIGS. 15-19 labeled with a letter D (e.g., 15D) illustrate a cross-sectional view of another portion of the IC structure showing a cross-sectional view along a x-z plane, as shown in the example coordinate system of FIG. 15A.

Turning to FIG. 14, the method 1400 begins with a process 1402 of providing a preliminary IC structure including an insulator material, a conductive material over the insulator material, and a first sacrificial material over the conductive material. The method 1400 continues with a process 1404 of forming openings in the first sacrificial material, the conductive material, and the insulator material, where the openings are arranged in two or more adjacent lines that are substantially parallel and staggered with respect to one another. The IC structure 1500 of FIGS. 15A-15D illustrates an example result of the processes 1402 and 1404. As can be seen in FIGS. 15A-15D, the preliminary IC structure 1500 includes an insulator material 1512 over a substrate 1502, a layer of conductive material 1540 over the insulator material, a layer of an insulator material 1513 over the conductive material 1540, and a sacrificial material 1506 over the insulator material 1513. The substrate 1502 may be an example of the support structure 302, discussed above with respect to FIG. 3A. The insulator materials 1512 and 1513 may be any suitable insulator materials, such as the ILDs discussed above, and may have the same or different material compositions.

The conductive material 1540 may be patterned in a later process to form control lines for an array of memory cells. In one example, the conductive material 1540 may include any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals. The sacrificial material 1506 may include any suitable sacrificial material, and may be an example of the sacrificial material 405 of FIG. 4A, discussed above.

In the examples illustrated in FIG. 15A-15D, the openings 1503 are cylindrical openings. Although FIGS. 15A-15D show the openings 1503 having a same width at both the top and bottom of the openings, the openings in a real fabricated structure may have tapered sidewalls and/or other non-straight features so that the openings are not perfectly cylindrical. In other examples, a cross-section of the openings 1503 along a plane substantially parallel to the substrate 1502 may have a non-circular or non-round shape. For example, a cross-section of the openings 1503 may have corners, and may be, for example, have a shape resembling a hexagon, parallelogram, rectangle, or other shape with four or more corners and sides. Forming the openings may involve multiple etching processes to remove the various materials in the stack of materials of the preliminary IC structure 1500 (e.g., to remove portions of the sacrificial material 1506, the insulator material 1513, the conductive material 1540, and the insulator material 1512 over the substrate 1502). Forming the openings may involve any suitable etching technique, e.g., a dry etch, such as e.g., radio frequency (RF) reactive ion etch (RIE) or inductively coupled plasma (ICP) RIE may be used to form the openings 1503. In some embodiments, the etch(es) performed in the process 1404 may include an anisotropic etch, using etchants in a form of e.g., chemically active ionized gas (i.e., plasma). In some embodiments, during the etch of the process 1404, the IC structure may be heated to elevated temperatures, e.g., to temperatures between about room temperature and 200 degrees Celsius, including all values and ranges therein, to promote that byproducts of the etch are made sufficiently volatile to be removed from the surface.

In the example illustrated in FIGS. 15A-15D, the openings 1503 are formed in staggered lines 1504-11, 1504-12, 1504-13, where the lines are substantially parallel and closely-spaced relative to other lines 1504-21, 1504-22, 1504-23 of openings, e.g., the line 1504-13 is further from the line 1504-21 than the line 1504-12. In the example illustrated in FIGS. 15A-15D, forming openings involves forming openings arranged groups of lines, e.g., two or more first lines 1504-11, 1504-12, 1504-13, and two or more second lines 1504-21, 1504-22, 1504-23, where the lines of each group are substantially parallel and staggered with respect to one another. In one such example, the adjacent lines of a particular group (e.g., the lines 1504-11 and 1504-12, or the lines 1504-12 and 1504-13) are separated from one another by a first distance, and the groups of lines are separated by a second distance that is greater than the first distance, e.g., to enable electrically isolating the subsequently formed control lines from one another. For example, the centers or centroids of openings in the line 1504-13 are at a distance 1531 from the center or centroid of openings in the line 1504-21, and the centers or centroids of the openings in the line 1504-13 are at a distance 1533 from the centers or centroids of the openings in the line 1504-12.

In one example, memory cells are to be formed in the openings 1503 in subsequent processes; therefore, the locations of the openings 1503 determine the locations of subsequently formed memory cells. Accordingly, in one example, groups of closely-spaced openings (e.g., the openings in the lines 1504-11, 1504-12, 1504-13) are spaced to enable the memory cells formed in those openings to be coupled with the same merged control line. In one example, the number of lines and spacing between adjacent openings may vary, and may be in accordance with the arrangement of spacing of memory cells in the examples described above. In the example illustrated in FIG. 15A, the openings are spaced and arranged such that the line 1504-13 is at an angle θ relative to a line 1535 connecting the centroids of neighboring memory cells in adjacent lines. In one such example, the angle θ may be less than 60 degrees, which is some examples, enables staggering three or more lines of subsequently formed memory cells, such as described above with respect to FIGS. 7A-7C.

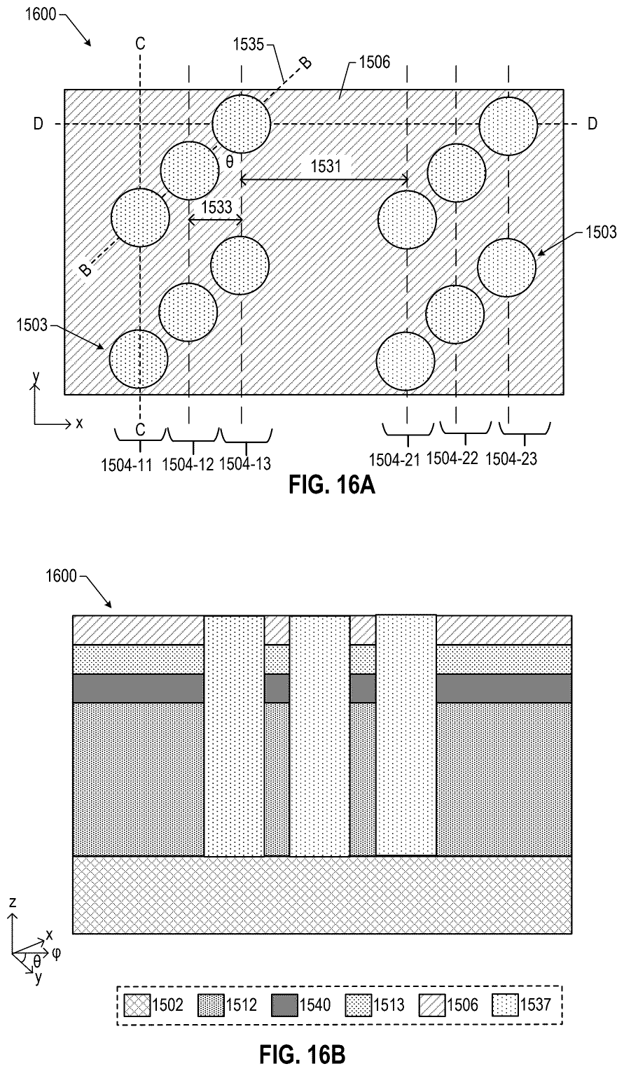

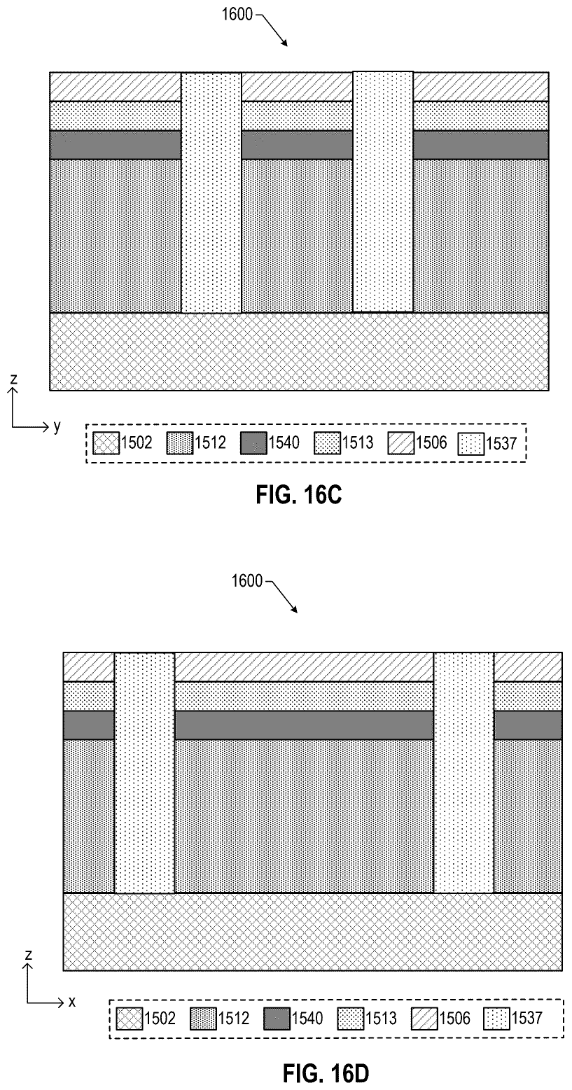

Referring again to FIG. 14, the method 1400 continues with a process 1406 of filling the first openings with a second sacrificial material. The IC structure 1600 of FIGS. 16A-16D illustrates an example result of the process 1406. As can be seen in FIGS. 16A-16D, the IC structure 1600 includes a second sacrificial material 1537 filling the openings 1503. In one example, the second sacrificial material 1537 is different from the sacrificial material 1506, to enable removal of the sacrificial material 1506 without removing the second sacrificial material 1537.

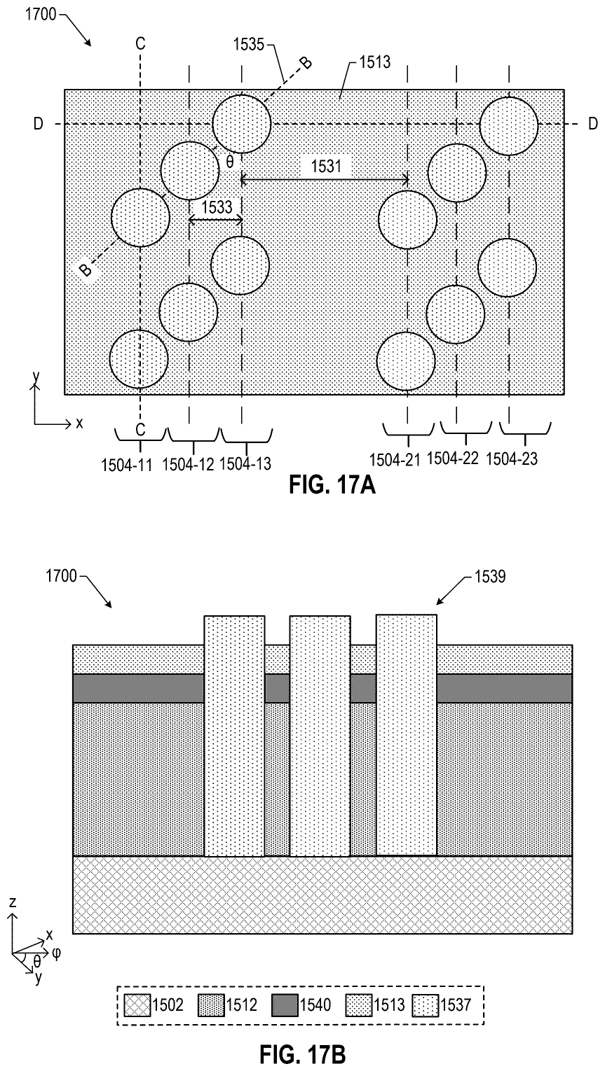

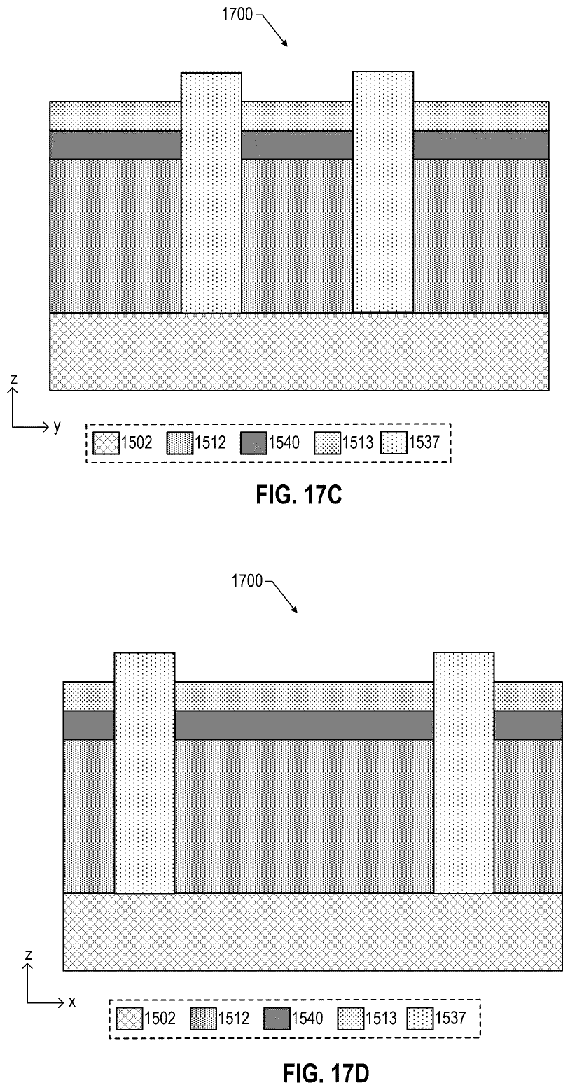

The method continues with a process 1408 of removing the first sacrificial material. The IC structure 1700 of FIGS. 17A-17D illustrates an example result of the process 1408. As can be seen in FIGS. 17A-17D, the sacrificial material 1506 has been removed from the IC structure 1700, exposing portions 1539 of the second sacrificial material 1537 protruding from the remaining stack of materials in which the openings 1503 were formed.

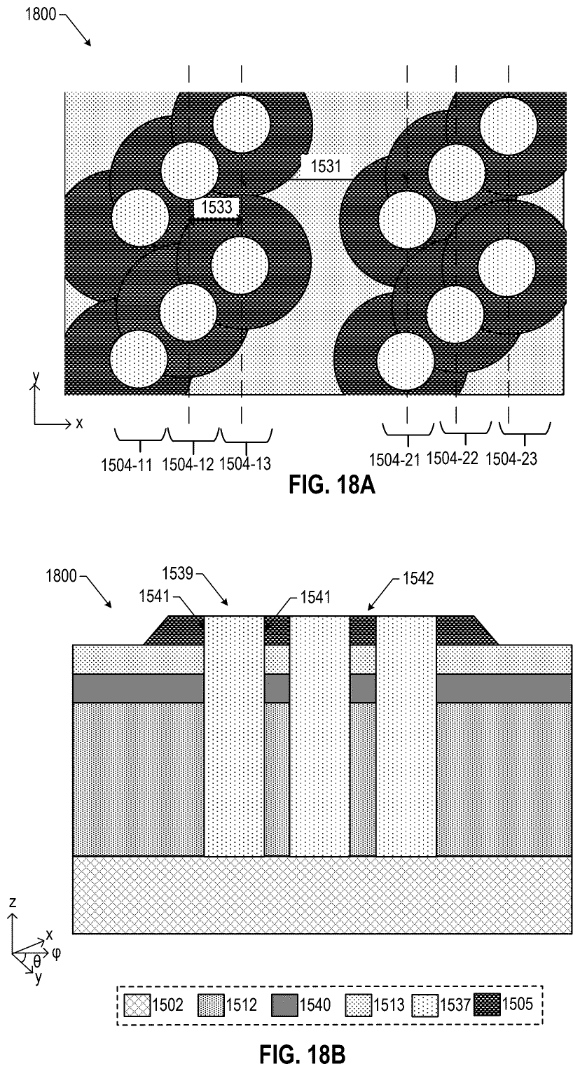

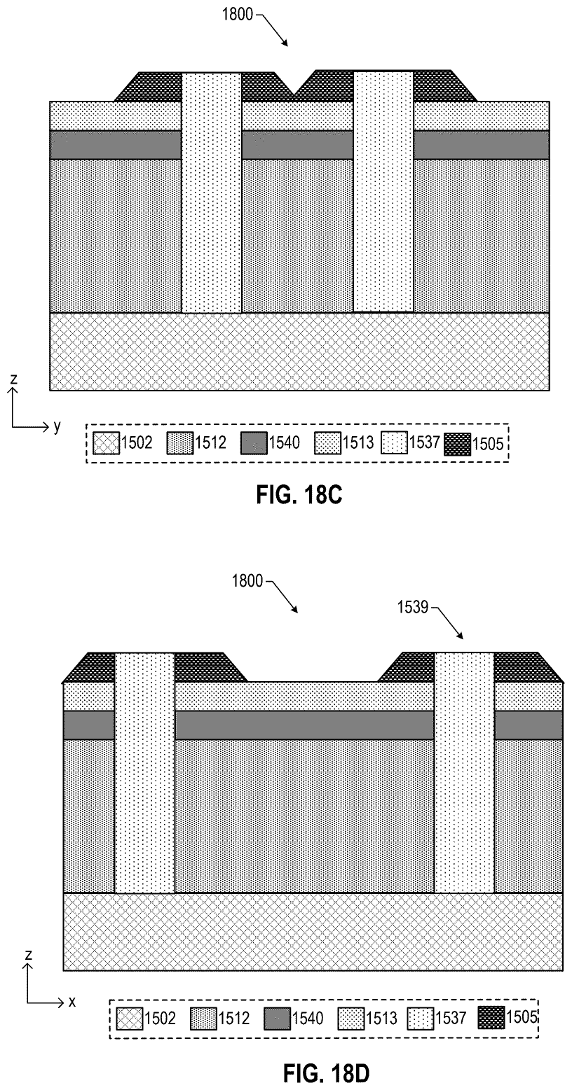

The method continues with a process 1410 of providing a third sacrificial material on side surfaces of exposed portions of the second sacrificial material, wherein the third sacrificial material includes a continuous portion of the third sacrificial material between adjacent lines of the two or more lines. The IC structure 1800 of FIGS. 18A-18D illustrates an example result of the process 1410. As can be seen in FIGS. 18A-18D, the IC structure 1800 includes a third sacrificial material 1505 on sidewalls 1541 of exposed portions 1539 of the second sacrificial material 1537. As can be seen in FIG. 18B, there is a continuous portion 1542 between openings of adjacent lines. For example, the third sacrificial material 1505 on sidewalls 1541 of adjacent portions 1539 merges together between openings that have a sufficiently small distance between them. In contrast, referring to FIG. 18D, the distance between the openings is large enough so that the third sacrificial material 1505 on sidewalls of the exposed portions 1539 does not merge together.

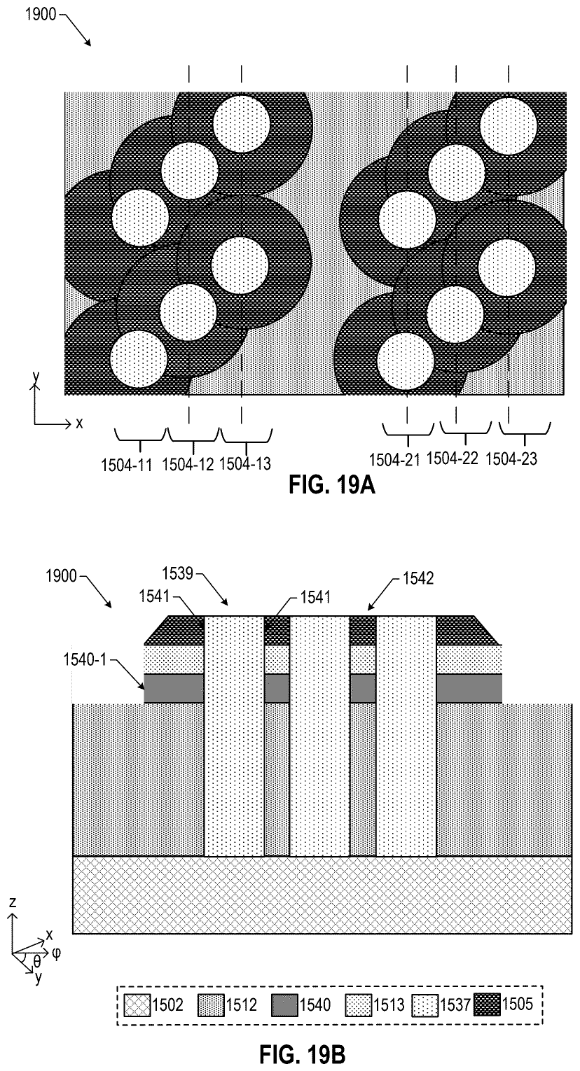

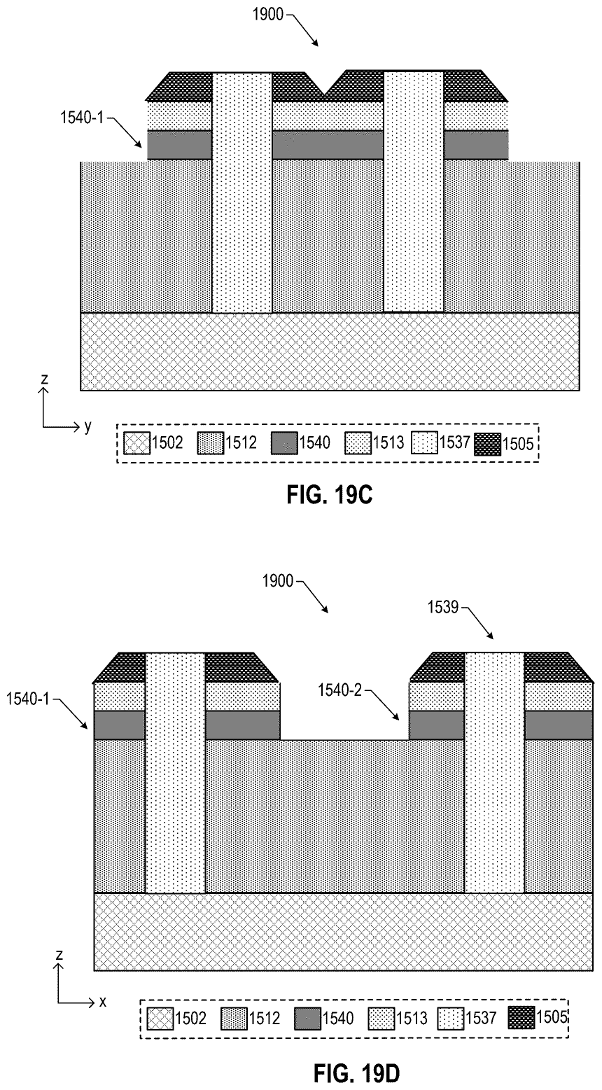

The method continues with a process 1412 of removing the conductive material exposed through second openings in third sacrificial material. The IC structure 1900 of FIGS. 19A-19D illustrates an example result of the process 1412. As can be seen in FIGS. 19A-19D, portions of the insulator material 1513 and portions of the conductive material 1540 exposed through openings in the third sacrificial material 1505 (e.g., openings in regions where the third sacrificial material 1505 did not merge together) have been removed in the IC structure 1900. Removing the insulator material 1513 and conductive material 1540 in regions not covered by the third sacrificial material 1505 may be accomplished with one or more etch techniques, such as the etch techniques discussed above with respect to the process 1404. By removing the portions of the conductive material 1540 exposed through openings in the third sacrificial material 1505, merged control lines can be formed. For example, referring to FIG. 19B, the conductive material 1540 around the sidewalls of the openings is merged together such that memory cells formed in those openings will be coupled with the same merged control line 1540-1. Similarly, referring to FIG. 19C, the conductive material 1540 around the sidewalls of the openings is merged together such that the memory cells formed in those openings will be coupled with the same merged control line 1540-1. In contrast, referring to FIG. 19D, the conductive material 1540 on the sidewalls of the openings is not merged together; therefore, the memory cell formed in the opening on the left of FIG. 19D will be coupled with the control line 1540-1, and the memory cell formed in the opening on the right side of FIG. 19D will be coupled with the control line 1540-2 that is electrically isolated from the control line 1540-1.

The method continues with a process 1414 of removing the second sacrificial material 1537 from the first openings 1503, and a process 1416 of forming memory cells in the first openings 1503, where the conductive material 1540 forms a control line for the memory cells. For example, memory cells in accordance with the examples described with respect to FIGS. 3A-3C, 4A-4C, 5A-5B, 6A-6B, or any other suitable memory cells may be formed in the openings 1503, and may be coupled with the merged control lines as described herein.

FIG. 20 is a flow diagram of another example method 2000 for fabricating an IC device with an array of memory cells and merged control lines, in accordance with some embodiments. FIGS. 21-24 are cross-sectional side views at various stages in the fabrication of an example IC structure according to the method of FIG. 20, in accordance with some embodiments.

The method 2000 of FIG. 20 differs from the method 1400 of FIG. 14 in the technique used to form a merged control line. In the method 1400 of FIG. 14, a sacrificial material is provided over a layer of conductive material around protruding portions of another sacrificial material, and the conductive material is removed in areas not covered by merged portions of the sacrificial material. In contrast, in the method 1400 of FIG. 14, the conductive material is provided around the protruding portions. Thus, according to example, in FIG. 14, a sacrificial material is used as a spacer material to form self-aligned merged control lines, and in FIG. 20, the conductive control line material is used as the spacer material directly to form self-aligned merged control lines.

Turning to FIG. 20, the method 2000 begins with a process 2002 of providing a preliminary IC structure including an insulator material and a first sacrificial material over the insulator material. The method 2000 continues with a process 2004 of forming openings in the first sacrificial material and the insulator material, where the openings are arranged in two or more adjacent lines that are substantially parallel and staggered with respect to one another. The IC structure 2100 of FIG. 21 illustrates an example result of the processes 2002 and 2004. As can be seen in FIG. 21, the preliminary IC structure 2100 includes an insulator material 1512 over a substrate 1502 and a sacrificial material 1506 over the insulator material 1513.

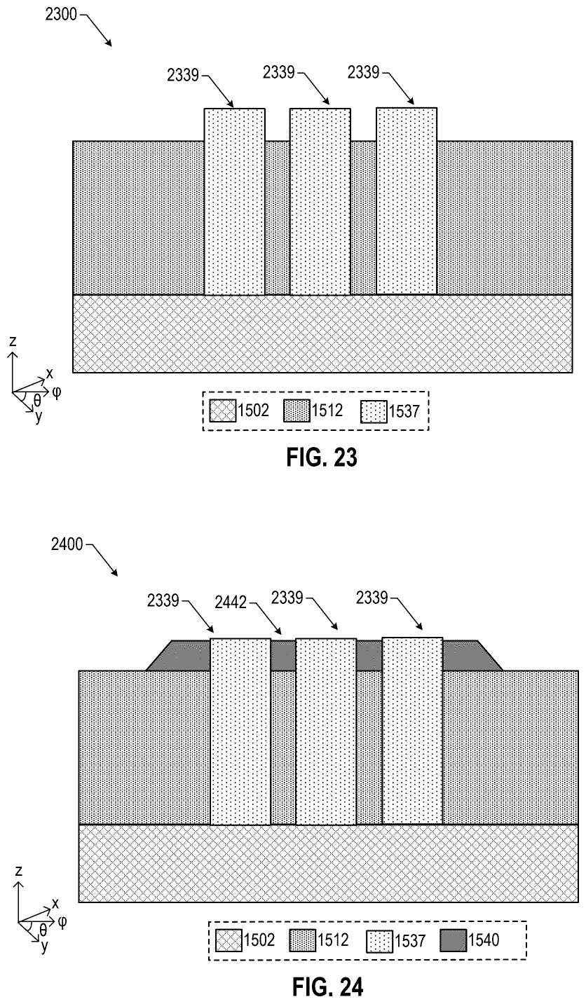

The method continues with the process 2006 of filling the openings with a second sacrificial material. The IC structure 2200 of FIG. 22 illustrates an example result of the process 2006. As can be seen in FIG. 22, the IC structure 2200 includes a second sacrificial material 1537 filling the openings 1503. The method continues with the process 2008 of removing the first sacrificial material. The IC structure 2300 of FIG. 23 illustrates an example result of the process 2008. As can be seen in FIG. 23, the sacrificial material 1506 has been removed from over the IC structure 2300, such that protruding portions 2339 of the second sacrificial material 1537 are exposed. The method continues with the process 2012 of providing a conductive material on side surfaces of exposed portions of the second sacrificial material, where the conductive material includes a continuous portion between adjacent lines. The IC structure 2400 of FIG. 24 illustrates an example result of the process 2012. As can be seen in FIG. 24, the IC structure 2400 includes continuous portions 2442 of the conductive material 1540 between adjacent openings. Referring again to FIG. 20, the method 2000 may then continue with the process 2016 of removing the second sacrificial material from the openings, and the process 2020 of forming memory cells in the openings, where the conductive material 1540 forms a control line for the memory cells.

Various arrangements of the IC devices 700, 800, 900, 1000, 1100, 1200, and 1300 as illustrated in FIGS. 7-13 do not represent an exhaustive set of IC devices implementing memory with vertical transistors and merged control lines as described herein, but merely provide examples of such devices, structures, and/or assemblies. In various embodiments, any of the features described with reference to one of the IC devices 700, 800, 900, 1000, 1100, 1200, and 1300 may be combined with any of the features described with reference to another one of the IC devices 700, 800, 900, 1000, 1100, 1200, and 1300. In general, the number and positions of various elements shown in FIGS. 7-13 is purely illustrative and, in various other embodiments, other numbers of these elements, provided in other locations relative to one another may be used in accordance with the general architecture considerations described herein.

Arrangements with one or more IC devices implementing memory with vertical transistors and merged control lines as disclosed herein may be included in any suitable electronic device. FIGS. 25-28 illustrate various examples of devices and components that may include one or more IC devices implementing memory with vertical transistors and merged control lines as disclosed herein.

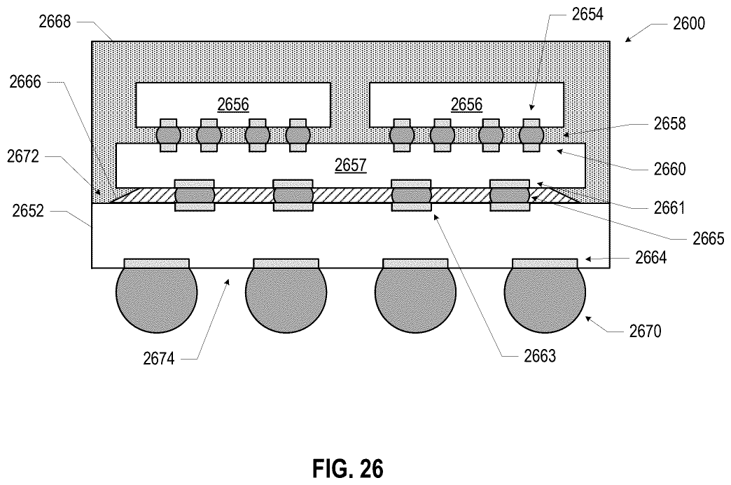

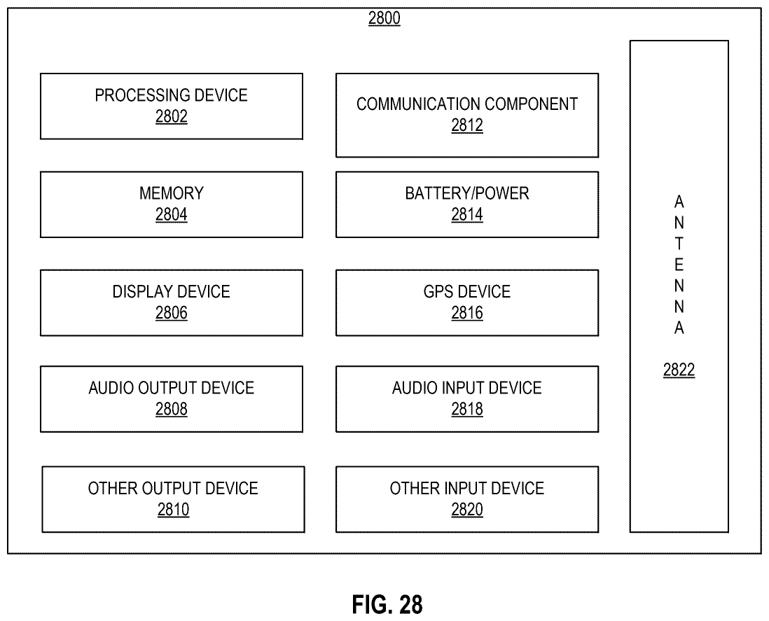

FIG. 25 illustrates top views of a wafer 1500 and dies 2502 that may include one or more IC devices implementing memory with vertical transistors and merged control lines in accordance with any of the embodiments disclosed herein. In some embodiments, the dies 2502 may be included in an IC package, in accordance with any of the embodiments disclosed herein. For example, any of the dies 2502 may serve as any of the dies 2656 in an IC package 2600 shown in FIG. 26. The wafer 2500 may be composed of semiconductor material and may include one or more dies 2502 having IC structures formed on a surface of the wafer 2500. Each of the dies 2502 may be a repeating unit of a semiconductor product that includes any suitable IC (e.g., ICs including one or more IC devices implementing memory with vertical transistors and merged control lines as described herein). After the fabrication of the semiconductor product is complete (e.g., after manufacture of any embodiment of the IC device implementing memory with vertical transistors and merged control lines as described herein), the wafer 2500 may undergo a singulation process in which each of the dies 2502 is separated from one another to provide discrete “chips” of the semiconductor product. In particular, devices that include one or more IC devices implementing memory with vertical transistors and merged control lines as disclosed herein may take the form of the wafer 2500 (e.g., not singulated) or the form of the die 2502 (e.g., singulated). The die 2502 may include supporting circuitry to route electrical signals to various memory cells, transistors, capacitors, as well as any other IC components. In some embodiments, the wafer 2500 or the die 2502 may implement or include a memory device (e.g., a hysteretic memory device), a logic device (e.g., an AND, OR, NAND, or NOR gate), or any other suitable circuit element. Multiple ones of these devices may be combined on a single die 2502. For example, a memory array formed by multiple memory devices may be formed on a same die 2502 as a processing device (e.g., the processing device 2802 of FIG. 28) or other logic that is configured to store information in the memory devices or execute instructions stored in the memory array.

FIG. 26 is a side, cross-sectional view of an example IC package 2600 that may include one or more IC devices implementing memory with vertical transistors and merged control lines in accordance with any of the embodiments disclosed herein. In some embodiments, the IC package 2600 may be a system-in-package (SiP).

The package substrate 2652 may be formed of a dielectric material (e.g., a ceramic, a buildup film, an epoxy film having filler particles therein, etc.), and may have conductive pathways extending through the dielectric material between the face 2672 and the face 2674, or between different locations on the face 2672, and/or between different locations on the face 2674.

The package substrate 2652 may include conductive contacts 2663 that are coupled to conductive pathways through the package substrate 2652, allowing circuitry within the dies 2656 and/or the interposer 2657 to electrically couple to various ones of the conductive contacts 2664 (or to other devices included in the package substrate 2652, not shown).

The IC package 2600 may include an interposer 2657 coupled to the package substrate 2652 via conductive contacts 2661 of the interposer 2657, first-level interconnects 2665, and the conductive contacts 2663 of the package substrate 2652. The first-level interconnects 2665 illustrated in FIG. 26 are solder bumps, but any suitable first-level interconnects 2665 may be used. In some embodiments, no interposer 2657 may be included in the IC package 2600; instead, the dies 2656 may be coupled directly to the conductive contacts 2663 at the face 2672 by first-level interconnects 2665.

The IC package 2600 may include one or more dies 2656 coupled to the interposer 2657 via conductive contacts 2654 of the dies 2656, first-level interconnects 2658, and conductive contacts 2660 of the interposer 2657. The conductive contacts 2660 may be coupled to conductive pathways (not shown) through the interposer 2657, allowing circuitry within the dies 2656 to electrically couple to various ones of the conductive contacts 2661 (or to other devices included in the interposer 2657, not shown). The first-level interconnects 2658 illustrated in FIG. 26 are solder bumps, but any suitable first-level interconnects 2658 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

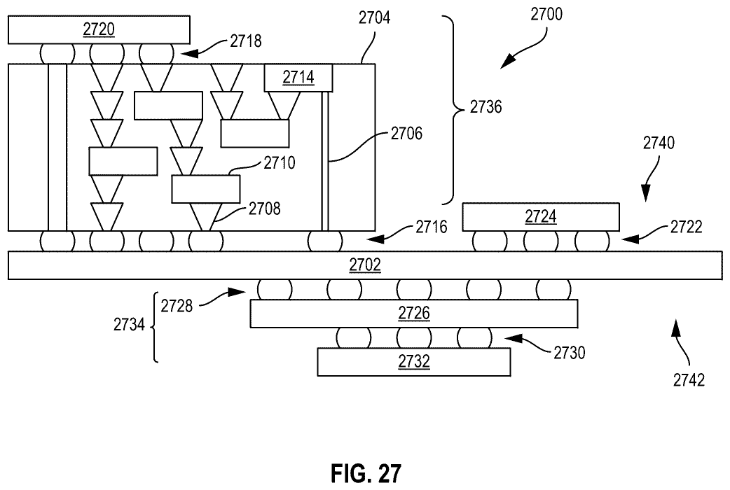

In some embodiments, an underfill material 2666 may be disposed between the package substrate 2652 and the interposer 2657 around the first-level interconnects 2665, and a mold compound 2668 may be disposed around the dies 2656 and the interposer 2657 and in contact with the package substrate 2652. In some embodiments, the underfill material 2666 may be the same as the mold compound 2668. Example materials that may be used for the underfill material 2666 and the mold compound 2668 are epoxy mold materials, as suitable. Second-level interconnects 2670 may be coupled to the conductive contacts 2664. The second-level interconnects 2670 illustrated in FIG. 26 are solder balls (e.g., for a ball grid array arrangement), but any suitable second-level interconnects 2670 may be used (e.g., pins in a pin grid array arrangement or lands in a land grid array arrangement). The second-level interconnects 2670 may be used to couple the IC package 2600 to another component, such as a circuit board (e.g., a motherboard), an interposer, or another IC package, as known in the art and as discussed below with reference to FIG. 27.

The dies 2656 may take the form of any of the embodiments of the die 2502 discussed herein (e.g., may include any of the embodiments of the IC devices implementing memory with vertical transistors and merged control lines as described herein). In embodiments in which the IC package 2600 includes multiple dies 2656, the IC package 2600 may be referred to as a multi-chip package (MCP). The dies 2656 may include circuitry to perform any desired functionality. For example, one or more of the dies 2656 may be logic dies (e.g., silicon-based dies), and one or more of the dies 2656 may be memory dies (e.g., high bandwidth memory), including embedded memory dies as described herein. In some embodiments, any of the dies 2656 may include one or more IC devices implementing memory with vertical transistors and merged control lines, e.g., as discussed above; in some embodiments, at least some of the dies 2656 may not include any IC devices implementing memory with vertical transistors and merged control lines.

The IC package 2600 illustrated in FIG. 26 may be a flip chip package, although other package architectures may be used. For example, the IC package 2600 may be a ball grid array (BGA) package, such as an embedded wafer-level ball grid array (eWLB) package. In another example, the IC package 2600 may be a wafer-level chip scale package (WLCSP) or a panel fan-out (FO) package. Although two dies 2656 are illustrated in the IC package 2600 of FIG. 26, an IC package 2600 may include any desired number of the dies 2656. An IC package 2600 may include additional passive components, such as surface-mount resistors, capacitors, and inductors disposed on the first face 2672 or the second face 2674 of the package substrate 2652, or on either face of the interposer 2657. More generally, an IC package 2600 may include any other active or passive components known in the art.

FIG. 27 is a cross-sectional side view of an IC device assembly 2700 that may include components having one or more IC devices implementing memory with vertical transistors and merged control lines in accordance with any of the embodiments disclosed herein. The IC device assembly 2700 includes a number of components disposed on a circuit board 2702 (which may be, e.g., a motherboard). The IC device assembly 2700 includes components disposed on a first face 2740 of the circuit board 2702 and an opposing second face 2742 of the circuit board 2702; generally, components may be disposed on one or both faces 2740 and 2742. In particular, any suitable ones of the components of the IC device assembly 2700 may include any of one or more IC devices implementing memory with vertical transistors and merged control lines in accordance with any of the embodiments disclosed herein; e.g., any of the IC packages discussed below with reference to the IC device assembly 2700 may take the form of any of the embodiments of the IC package 2600 discussed above with reference to FIG. 26 (e.g., may include one or more IC devices implementing memory with vertical transistors and merged control lines provided on a die 2656).

In some embodiments, the circuit board 2702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2702. In other embodiments, the circuit board 2702 may be a non-PCB substrate.

The IC device assembly 2700 illustrated in FIG. 27 includes a package-on-interposer structure 2736 coupled to the first face 2740 of the circuit board 2702 by coupling components 2716. The coupling components 2716 may electrically and mechanically couple the package-on-interposer structure 2736 to the circuit board 2702, and may include solder balls (e.g., as shown in FIG. 27), male and female portions of a socket, an adhesive, an underfill material, and/or any other suitable electrical and/or mechanical coupling structure.

The package-on-interposer structure 2736 may include an IC package 2720 coupled to an interposer 2704 by coupling components 2718. The coupling components 2718 may take any suitable form for the application, such as the forms discussed above with reference to the coupling components 2716. The IC package 2720 may be or include, for example, a die (the die 2502 of FIG. 25), an IC device, or any other suitable component. In particular, the IC package 2720 may include one or more IC devices implementing memory with vertical transistors and merged control lines as described herein. Although a single IC package 2720 is shown in FIG. 27, multiple IC packages may be coupled to the interposer 2704; indeed, additional interposers may be coupled to the interposer 2704. The interposer 2704 may provide an intervening substrate used to bridge the circuit board 2702 and the IC package 2720. Generally, the interposer 2704 may spread a connection to a wider pitch or reroute a connection to a different connection. For example, the interposer 2704 may couple the IC package 2720 (e.g., a die) to a BGA of the coupling components 2716 for coupling to the circuit board 2702. In the embodiment illustrated in FIG. 27, the IC package 2720 and the circuit board 2702 are attached to opposing sides of the interposer 2704; in other embodiments, the IC package 2720 and the circuit board 2702 may be attached to a same side of the interposer 2704. In some embodiments, three or more components may be interconnected by way of the interposer 2704.

The interposer 2704 may be formed of an epoxy resin, a fiberglass-reinforced epoxy resin, a ceramic material, or a polymer material such as polyimide. In some implementations, the interposer 2704 may be formed of alternate rigid or flexible materials that may include the same materials described above for use in a semiconductor substrate, such as silicon, germanium, and other group III-V and group IV materials. The interposer 2704 may include metal interconnects 2708 and vias 2710, including but not limited to through-silicon vias (TSVs) 2706. The interposer 2704 may further include embedded devices 2714, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as RF devices, power amplifiers, power management devices, antennas, arrays, sensors, and microelectromechanical systems (MEMS) devices may also be formed on the interposer 2704. The package-on-interposer structure 2736 may take the form of any of the package-on-interposer structures known in the art.

The IC device assembly 2700 may include an IC package 2724 coupled to the first face 2740 of the circuit board 2702 by coupling components 2722. The coupling components 2722 may take the form of any of the embodiments discussed above with reference to the coupling components 2716, and the IC package 2724 may take the form of any of the embodiments discussed above with reference to the IC package 2720.

The IC device assembly 2700 illustrated in FIG. 27 includes a package-on-package structure 2734 coupled to the second face 2742 of the circuit board 2702 by coupling components 2728. The package-on-package structure 2734 may include an IC package 2726 and an IC package 2732 coupled together by coupling components 2730 such that the IC package 2726 is disposed between the circuit board 2702 and the IC package 2732. The coupling components 2728 and 2730 may take the form of any of the embodiments of the coupling components 2716 discussed above, and the IC packages 2726 and 2732 may take the form of any of the embodiments of the IC package 2720 discussed above. The package-on-package structure 2734 may be configured in accordance with any of the package-on-package structures known in the art.

FIG. 28 is a block diagram of an example computing device 2800 that may include one or more components with one or more IC devices implementing memory with vertical transistors and merged control lines in accordance with any of the embodiments disclosed herein. For example, any suitable ones of the components of the computing device 2800 may include a die (e.g., the die 2502 (FIG. 25)) including one or more IC devices implementing memory with vertical transistors and merged control lines in accordance with any of the embodiments disclosed herein. Any of the components of the computing device 2800 may include an IC package 2600 (FIG. 26). Any of the components of the computing device 2800 may include an IC device assembly 2700 (FIG. 27).

A number of components are illustrated in FIG. 28 as included in the computing device 2800, but any one or more of these components may be omitted or duplicated, as suitable for the application. In some embodiments, some or all of the components included in the computing device 2800 may be attached to one or more motherboards. In some embodiments, some or all of these components are fabricated onto a single SoC die.

Additionally, in various embodiments, the computing device 2800 may not include one or more of the components illustrated in FIG. 28, but the computing device 2800 may include interface circuitry for coupling to the one or more components. For example, the computing device 2800 may not include a display device 2806, but may include display device interface circuitry (e.g., a connector and driver circuitry) to which a display device 2806 may be coupled. In another set of examples, the computing device 2800 may not include an audio input device 2818 or an audio output device 2808 but may include audio input or output device interface circuitry (e.g., connectors and supporting circuitry) to which an audio input device 2818 or audio output device 2808 may be coupled.

The computing device 2800 may include a processing device 2802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2800 may include a memory 2804, which may itself include one or more memory devices such as volatile memory (e.g., DRAM), nonvolatile memory (e.g., read-only memory (ROM)), flash memory, solid state memory, and/or a hard drive. In some embodiments, the memory 2804 may include memory that shares a die with the processing device 2802. This memory may be used as cache memory and may include embedded hysteretic memory, e.g., one or more IC devices implementing memory with vertical transistors and merged control lines as described herein.

In some embodiments, the computing device 2800 may include a communication chip 2812 (e.g., one or more communication chips). For example, the communication chip 2812 may be configured for managing wireless communications for the transfer of data to and from the computing device 2800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2812 may operate in accordance with other wireless protocols in other embodiments. The computing device 2800 may include an antenna 2822 to facilitate wireless communications and/or to receive other wireless communications (such as AM or FM radio transmissions).

In some embodiments, the communication chip 2812 may manage wired communications, such as electrical, optical, or any other suitable communication protocols (e.g., the Ethernet). As noted above, the communication chip 2812 may include multiple communication chips. For instance, a first communication chip 2812 may be dedicated to shorter-range wireless communications such as Wi-Fi or Bluetooth, and a second communication chip 2812 may be dedicated to longer-range wireless communications such as global positioning system (GPS), EDGE, GPRS, CDMA, WiMAX, LTE, EV-DO, or others. In some embodiments, a first communication chip 2812 may be dedicated to wireless communications, and a second communication chip 2812 may be dedicated to wired communications.

The computing device 2800 may include battery/power circuitry 2814. The battery/power circuitry 2814 may include one or more energy storage devices (e.g., batteries or capacitors) and/or circuitry for coupling components of the computing device 2800 to an energy source separate from the computing device 2800 (e.g., AC line power).

The computing device 2800 may include a display device 2806 (or corresponding interface circuitry, as discussed above). The display device 2806 may include any visual indicators, such as a heads-up display, a computer monitor, a projector, a touchscreen display, a liquid crystal display (LCD), a light-emitting diode display, or a flat panel display, for example.

The computing device 2800 may include an audio output device 2808 (or corresponding interface circuitry, as discussed above). The audio output device 2808 may include any device that generates an audible indicator, such as speakers, headsets, or earbuds, for example.

The computing device 2800 may include an audio input device 2818 (or corresponding interface circuitry, as discussed above). The audio input device 2818 may include any device that generates a signal representative of a sound, such as microphones, microphone arrays, or digital instruments (e.g., instruments having a musical instrument digital interface (MIDI) output).

The computing device 2800 may include a GPS device 2816 (or corresponding interface circuitry, as discussed above). The GPS device 2816 may be in communication with a satellite-based system and may receive a location of the computing device 2800, as known in the art.

The computing device 2800 may include an other output device 2810 (or corresponding interface circuitry, as discussed above). Examples of the other output device 2810 may include an audio codec, a video codec, a printer, a wired or wireless transmitter for providing information to other devices, or an additional storage device.

The computing device 2800 may include an other input device 2820 (or corresponding interface circuitry, as discussed above). Examples of the other input device 2820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2800 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2800 may be any other electronic device that processes data.

The following paragraphs provide various examples of the embodiments disclosed herein.
Example 1 provides an IC device, including a substrate; a plurality of memory cells arranged in two or more lines staggered with respect to one another over the substrate (e.g., in a same plane over the substrate, where the plane is parallel to the substrate), where the two or more lines include a first line and a second line adjacent to the first line; and a control line (e.g., a conductive line) coupled with the plurality of memory cells, where: the control line is substantially parallel to the two or more lines, the control line includes a continuous conductive material between a first memory cell of the first line and a second memory cell of the second line, where the second memory cell is a nearest neighboring memory cell of the second line to the first memory cell, and a line between a first centroid of the first memory cell and a second centroid of the second memory cell is at an angle of less than 60 degrees relative to the control line.
Example 2 provides the IC device of example 1, where: the plurality of memory cells is arranged in three or more lines staggered with respect to one another; and the continuous conductive material is between the second memory cell and a third memory cell of a third line of the three or more lines.
Example 3 provides the IC device of any one of examples 1 or 2, where the control line is one of a plurality of first control lines, and where the IC device further includes a plurality of second control lines substantially orthogonal to the plurality of first control lines, where: each of the plurality of second control lines is coupled with a different one of the plurality of memory cells, the plurality of first control lines has a first pitch, and the plurality of second control lines has a second pitch that is smaller than the first pitch.
Example 4 provides the IC device of example 3, where: the IC device includes an insulator material over the substrate, where: an individual memory cell of the plurality of memory cells is in an opening in the insulator material, and where the memory cell includes a sacrificial material around sidewalls of the opening in a layer between the plurality of first control lines and the plurality of second control lines.
Example 5 provides the IC device of example 4, where: the continuous conductive material includes a first portion between the sidewalls of the opening and the insulator material, where the first portion has a first width; and the sacrificial material includes a second portion between the sidewalls of the opening and the insulator material, where the second portion has a second width, and where the second width is about the same as the first width.
Example 6 provides the IC device of example 4 or 5, where: the individual memory cell includes a semiconductor material on sidewalls of the opening, and where the continuous conductive material is in contact with the semiconductor material of the first memory cell and the semiconductor material of the second memory cell.
Example 7 provides the IC device of example 6, where: the control line at least partially wraps around the semiconductor material of the first memory cell and the second memory cell.
Example 8 provides the IC device of any one of examples 4-7, where: a cross-section of the individual memory cell along a plane substantially parallel to the substrate has a shape that includes four or more sides.
Example 9 provides the IC device of example 1 or 2, where: the angle is in a range of 20-70 degrees, 30-60 degrees, or 30-55 degrees.
Example 10 provides the IC device of any one of examples 1-9, where: a first centroid of the first memory cell is at a first distance from a second centroid of the second memory cell; the first centroid of the first memory cell is at a second distance from a third centroid of a third memory cell of the first line, where the third memory cell is a nearest neighboring memory cell of the first line to the first memory cell; and the second distance is greater than the first distance.
Example 11 provides the IC device of any one of examples 1-10, where the control line is a first bitline of a plurality of bitlines, where the plurality of memory cells is a first plurality of memory cells, and where the IC device further includes a second plurality of memory cells; a second bitline of the plurality of bitlines coupled with the second plurality of memory cells; and a plurality of wordlines substantially orthogonal to the plurality of wordlines, where: the plurality of wordlines includes a first wordline and a second wordline adjacent to the first wordline, the first memory cell of the first plurality of memory cells and a third memory cell of the second plurality of memory cells are coupled with the first wordline and separated by a first distance, a fourth memory cell of the first plurality of memory cells and a fifth memory cell of the second plurality of memory cells are coupled with the second wordline and separated by a second distance, and the first distance is different from the second distance.
Example 12 provides the IC device of any one of examples 1-11, where: the IC device includes an insulator material over the substrate; the first memory cell and the second memory cell are in respective openings in the insulator material; the first memory cell and the second memory cell include a semiconductor material on sidewalls of the respective openings; the control line includes a portion of the continuous conductive material between the semiconductor material of the first memory cell and the insulator material; and the portion has a width that is greater than or equal to half a distance between the semiconductor material of the first memory cell and the semiconductor material of the second memory cell.
Example 13 provides an IC device, including first memory cells oriented in a first line; second memory cells oriented in a second line that is substantially parallel to and adjacent to the first line, where the second memory cells are offset from the first memory cells along an axis substantially parallel to the first line; third memory cells oriented in a third line that is substantially parallel to and adjacent to the second line, where the third memory cells are offset from the second memory cells along the axis; and a control line coupled with the first memory cells, the second memory cells, and the third memory cells, where the control line includes a first continuous portion between a first memory cell of the first memory cells and a second memory cell of the second memory cells, and a second continuous portion between the second memory cell and a third memory cell of the third memory cells.
Example 14 provides the IC device of example 13, further including fourth memory cells oriented in a fourth line that is substantially parallel to and adjacent to the third line, where the fourth memory cells are offset from the third memory cells along the axis, where the control line is coupled with the fourth memory cells.
Example 15 provides the IC device of example 13 or 14, where: the control line includes a continuous portion of conductive material in contact with a channel material of the first memory cell, the second memory cell, and the third memory cell.
Example 16 provides the IC device of any one of examples 13-15, where the control line is a first control line, and where the IC device further includes a plurality of second control lines substantially perpendicular to the first control line, where: the first control line has a first width, where the first width is a dimension of the first control line in a plane substantially parallel to a substrate over which the first control line is disposed, and a second control line of the plurality of second control lines has a second width that is smaller than the first width.
Example 17 provides the IC structure according to any one of examples 1-16, where the IC structure includes or is a part of a central processing unit.
Example 18 provides the IC structure according to any one of examples 1-17, where the IC structure includes or is a part of a memory device.
Example 19 provides the IC structure according to any one of examples 1-18, where the IC structure includes or is a part of a logic circuit.
Example 20 provides the IC structure according to any one of examples 1-19, where the IC structure includes or is a part of input/output circuitry.
Example 21 provides the IC structure according to any one of examples 1-20, where the IC structure includes or is a part of a field programmable gate array transceiver.
Example 22 provides the IC structure according to any one of examples 1-21, where the IC structure includes or is a part of a field programmable gate array logic.
Example 23 provides the IC structure according to any one of examples 1-22, where the IC structure includes or is a part of a power delivery circuitry.
Example 24 provides an IC package that includes an IC die including an IC structure according to any one of examples 1-16; and a further IC component, coupled to the IC die.
Example 25 provides the IC package according to example 24, where the further IC component includes a package substrate.
Example 26 provides the IC package according to example 24, where the further IC component includes an interposer.
Example 27 provides the IC package according to example 24, where the further IC component includes a further IC die.
Example 28 provides a computing device that includes a carrier substrate and an IC structure coupled to the carrier substrate, where the IC structure is an IC structure according to any one of examples 1-16, or the IC structure is included in the IC package according to any one of claims 24-27.
Example 29 provides the computing device according to example 28, where the computing device is a wearable or handheld computing device.
Example 30 provides the computing device according to examples 28 or 29, where the computing device further includes one or more communication chips.
Example 31 provides the computing device according to any one of examples 28-30, where the computing device further includes an antenna.
Example 32 provides the computing device according to any one of examples 28-31, where the carrier substrate is a motherboard.
Example 33 provides a method of fabricating an IC structure, the method including providing a preliminary IC structure including an insulator material, a conductive material over the insulator material, and a first sacrificial material over the conductive material; forming first openings in the first sacrificial material, the conductive material, and the insulator material, where the first openings are arranged in two or more lines, and where the two or more lines are substantially parallel and staggered with respect to one another; filling the first openings with a second sacrificial material; removing the first sacrificial material; providing a third sacrificial material on side surfaces of exposed portions of the second sacrificial material, where the third sacrificial material includes a continuous portion of the third sacrificial material between adjacent lines of the two or more lines; removing the conductive material exposed through second openings in third sacrificial material; removing the second sacrificial material from the first openings; and forming memory cells in the first openings, where the conductive material forms a control line for the memory cells.
Example 34 provides the method of example 33, where: forming the first openings includes forming the first openings with a hexagonal cross-section; and forming the memory cells includes forming the memory cells with a hexagonal cross-section in the first openings.
Example 35 provides the method of example 33 or 34, where: providing the third sacrificial material includes providing the third sacrificial material having a width that is greater than or equal to half a distance between the side surfaces of the exposed portions between the adjacent lines.
Example 36 provides the method of any one of examples 33-35, further including removing the third sacrificial material.
Example 37 provides the method according to any one of examples 33-36, where the IC structure is an IC structure according to any one of the preceding claims.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a substrate;
a plurality of memory cells arranged in two or more lines staggered with respect to one another over the substrate, wherein the two or more lines include a first line and a second line adjacent to the first line; and
a conductive line coupled with the plurality of memory cells, wherein:
the conductive line is substantially parallel to the two or more lines, the conductive line includes a continuous conductive material between a first memory cell of the first line and a second memory cell of the second line, wherein the second memory cell is a nearest neighboring memory cell of the second line to the first memory cell, and a line between a first approximate geometric center of the first memory cell and a second approximate geometric center of the second memory cell is at an angle of less than 60 degrees relative to the conductive line.

2. The IC device of claim 1, wherein:
the plurality of memory cells is arranged in three or more lines staggered with respect to one another; and
the continuous conductive material is between the second memory cell and a third memory cell of a third line of the three or more lines.

3. The IC device of claim 1, wherein the conductive line is one of a plurality of first conductive lines, and wherein the IC device further comprises:
a plurality of second conductive lines substantially orthogonal to the plurality of first conductive lines, wherein:
each of the plurality of second conductive lines is coupled with a different one of the plurality of memory cells, the plurality of first conductive lines has a first pitch, and the plurality of second conductive lines has a second pitch that is smaller than the first pitch.

4. The IC device of claim 3, wherein:
the IC device includes an insulator material over the substrate, wherein:
an individual memory cell of the plurality of memory cells is in an opening in the insulator material, and wherein the memory cell includes a sacrificial material around sidewalls of the opening in a layer between the plurality of first conductive lines and the plurality of second conductive lines.

5. The IC device of claim 4, wherein:
the continuous conductive material includes a first portion between the sidewalls of the opening and the insulator material, wherein the first portion has a first width; and
the sacrificial material includes a second portion between the sidewalls of the opening and the insulator material, wherein the second portion has a second width, and wherein the second width is about the same as the first width.

6. The IC device of claim 4, wherein:
the individual memory cell includes a semiconductor material on sidewalls of the opening, and wherein the continuous conductive material is in contact with the semiconductor material of the first memory cell and the semiconductor material of the second memory cell.

7. The IC device of claim 6, wherein:
the conductive line at least partially wraps around the semiconductor material of the first memory cell and the second memory cell.

8. The IC device of claim 4, wherein:
a cross-section of the individual memory cell along a plane substantially parallel to the substrate has a shape that includes four or more sides.

9. The IC device of claim 1, wherein:
the angle is in a range of 30-55 degrees.

10. The IC device of claim 1, wherein:
the first approximate geometric center of the first memory cell is at a first distance from a second approximate geometric center of the second memory cell;
the first approximate geometric center of the first memory cell is at a second distance from a third approximate geometric center of a third memory cell of the first line, wherein the third memory cell is a nearest neighboring memory cell of the first line to the first memory cell; and
the second distance is greater than the first distance.

11. The IC device of claim 1, wherein the conductive line is a first bitline of a plurality of bitlines, wherein the plurality of memory cells is a first plurality of memory cells, and wherein the IC device further comprises:
a second plurality of memory cells;
a second bitline of the plurality of bitlines coupled with the second plurality of memory cells; and
a plurality of wordlines substantially orthogonal to the plurality of wordlines, wherein:
the plurality of wordlines includes a first wordline and a second wordline adjacent to the first wordline, the first memory cell of the first plurality of memory cells and a third memory cell of the second plurality of memory cells are coupled with the first wordline and separated by a first distance, a fourth memory cell of the first plurality of memory cells and a fifth memory cell of the second plurality of memory cells are coupled with the second wordline and separated by a second distance, and the first distance is different from the second distance.

12. The IC device of claim 1, wherein:
the IC device includes an insulator material over the substrate;
the first memory cell and the second memory cell are in respective openings in the insulator material;
the first memory cell and the second memory cell include a semiconductor material on sidewalls of the respective openings;
the conductive line includes a portion of the continuous conductive material between the semiconductor material of the first memory cell and the insulator material; and
the portion has a width that is greater than or equal to half a distance between the semiconductor material of the first memory cell and the semiconductor material of the second memory cell.

13. An integrated circuit (IC) device, comprising:
first memory cells oriented in a first line;
second memory cells oriented in a second line that is substantially parallel to and adjacent to the first line, wherein the second memory cells are offset from the first memory cells along an axis substantially parallel to the first line;
third memory cells oriented in a third line that is substantially parallel to and adjacent to the second line, wherein the third memory cells are offset from the second memory cells along the axis; and
a conductive line coupled with the first memory cells, the second memory cells, and the third memory cells, wherein the conductive line includes:
a first continuous portion between a first memory cell of the first memory cells and a second memory cell of the second memory cells, and a second continuous portion between the second memory cell and a third memory cell of the third memory cells.

14. The IC device of claim 13, further comprising:
fourth memory cells oriented in a fourth line that is substantially parallel to and adjacent to the third line, wherein the fourth memory cells are offset from the third memory cells along the axis, wherein the conductive line is coupled with the fourth memory cells.

15. The IC device of claim 13, wherein:
the conductive line includes a continuous portion of conductive material in contact with a channel material of the first memory cell, the second memory cell, and the third memory cell.

16. The IC device of claim 13, wherein the conductive line is a first conductive line, and wherein the IC device further comprises:
a plurality of second conductive lines substantially perpendicular to the first conductive line, wherein:
the first conductive line has a first width, wherein the first width is a dimension of the first conductive line in a plane substantially parallel to a substrate over which the first conductive line is disposed, and a second conductive line of the plurality of second conductive lines has a second width that is smaller than the first width.

17. A method of fabricating an integrated circuit (IC) structure, the method comprising:
providing a preliminary IC structure including an insulator material, a conductive material over the insulator material, and a first sacrificial material over the conductive material;
forming first openings in the first sacrificial material, the conductive material, and the insulator material, wherein the first openings are arranged in two or more lines, and wherein the two or more lines are substantially parallel and staggered with respect to one another;
filling the first openings with a second sacrificial material;
removing the first sacrificial material;
providing a third sacrificial material on side surfaces of exposed portions of the second sacrificial material, wherein the third sacrificial material includes a continuous portion of the third sacrificial material between adjacent lines of the two or more lines;
removing the conductive material exposed through second openings in third sacrificial material;
removing the second sacrificial material from the first openings; and
forming memory cells in the first openings, wherein the conductive material forms a conductive line for the memory cells.

18. The method of claim 17, wherein:
forming the first openings includes:
forming the first openings with a hexagonal cross-section; and
forming the memory cells includes:
forming the memory cells with a hexagonal cross-section in the first openings.

19. The method of claim 17, wherein:
providing the third sacrificial material includes:
providing the third sacrificial material having a width that is greater than or equal to half a distance between the side surfaces of the exposed portions between the adjacent lines.

20. The method of claim 17, further comprising:
removing the third sacrificial material.
